(19) United States
(12) Patent Application Publication
(10) Pub. No.: US 2025/0311523 A1
(43) Pub. Date: Oct. 2, 2025

(54) PHOTOELECTRIC CONVERSION DEVICE MATERIAL AND PHOTOELECTRIC CONVERSION DEVICE FOR IMAGING

(71) Applicant: NIPPON STEEL CHEMICAL & MATERIAL CO., LTD., Tokyo (JP)

(72) Inventors: Munetomo INOUE, Tokyo (JP); Kentaro HAYASHI, Tokyo (JP)

(73) Assignee: NIPPON STEEL CHEMICAL & MATERIAL CO., LTD., Tokyo (JP)

(21) Appl. No.: 18/865,860

(22) PCT Filed: May 23, 2023
(86) PCT No.: PCT/JP2023/019042

§ 371 Date: Nov. 14, 2024

(30) Foreign Application Priority Data
May 25, 2022 (JP) 2022-084995

(51) Int. Cl. H10K 39/32; H10K 85/60

(52) U.S. Cl. CPC H10K 39/32; H10K 85/626; H10K 85/636; H10K 85/654; H10K 85/656; H10K 85/6572; H10K 85/6574; H10K 85/6576

(57) ABSTRACT

Provided is a material for a photoelectric conversion device for imaging and a photoelectric conversion device for imaging that achieve higher sensitivity and higher resolution. A material for a photoelectric conversion device represented by the general formula (1) or (2), and a photoelectric conversion device for imaging, including a photoelectric conversion layer and an electron blocking layer between two electrodes, wherein at least one of these layers contains the above material.

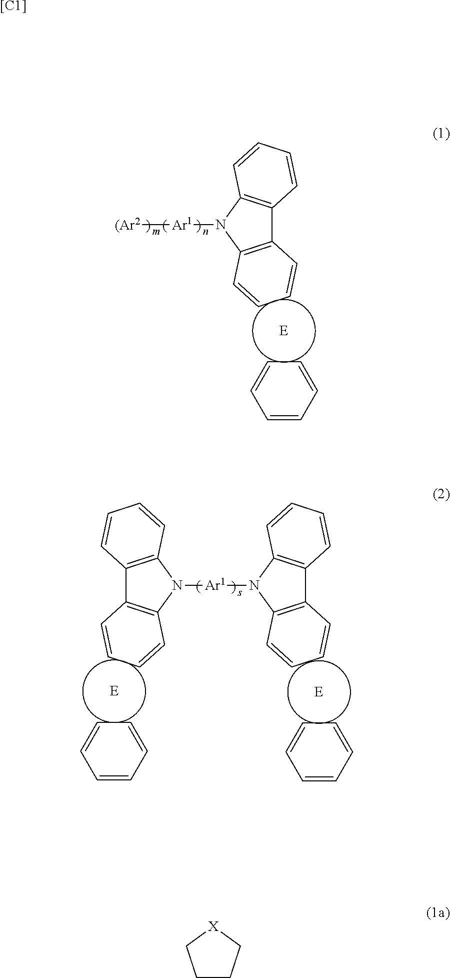

The ring E independently represents a heterocyclic ring condensed with an adjacent ring at any position and represented by the formula (1a). Ar¹, Ar², Ar⁵, and Ar⁶ each independently represent a diarylamino group having 12 to 30 carbon atoms, an arylheteroarylamino group having 12 to 30 carbon atoms, a diheteroarylamino group having 12 to 30 carbon atoms, an aromatic hydrocarbon group having 6 to 30 carbon atoms, or a heteroaromatic group having 4 to 18 carbon atoms, and at least one of Ar¹, Ar², Ar⁵, or Ar⁶ represents the amino group or a group in which the amino group is further condensed.

### TECHNICAL FIELD

The present invention relates to a material for a photoelectric conversion element (device) and a photoelectric conversion device using the same, and particularly to a material for a photoelectric conversion device useful for an imaging device.

In recent years, development of an organic electronic device using a thin film formed with an organic semiconductor is in progress. Examples thereof include an electroluminescent device, a solar cell, a transistor device, and a photoelectric conversion device. In particular, development of an organic EL device, which is an electroluminescent device with an organic substance, is most advanced among them. The applications for smartphones, TV and the like are in progress, and development for a purpose of further higher functionality is continuously conducted.

On the photoelectric conversion device, a device using a P-N junction of an inorganic semiconductor, such as silicon, has been conventionally developed and practically used, and made are investigations for high functionalization of a digital camera and a camera for a smartphone and investigation for application for a monitoring camera, a sensor for an automobile, and the like. However, problems for these various uses include improving sensitivity and micronizing a pixel (improving resolution). For the photoelectric conversion device using an inorganic semiconductor, a mainly adopted method for obtaining a color image is disposing color filters corresponding to RGB, which are the three primary colors of light, on a light receiving part of the photoelectric conversion device. This method has problems in terms of utilization efficiency of an incident light and resolution, because the method disposes the RGB color filters on a plane (Non Patent Literature 1 and 2).

As a solution for such problems of the photoelectric conversion device, a photoelectric conversion device using an organic semiconductor instead of the inorganic semiconductor is developed (Non Patent Literature 1 and 2). This utilizes an ability to selectively absorb only light having a specific wavelength region with high sensitivity that the organic semiconductor has, and proposed is stacking photoelectric conversion devices composed of organic semiconductors corresponding to the three primary colors of light to solve the problem of improving the sensitivity and improving the resolution. A device in which a photoelectric conversion device composed of the organic semiconductor and a photoelectric conversion device composed of the inorganic semiconductor are stacked is also proposed (Non Patent Literature 3).

Here, the photoelectric conversion device using the organic semiconductor is a device having a photoelectric conversion layer composed of a thin film of the organic semiconductor between two electrodes, wherein a hole blocking layer and/or an electron blocking layer is disposed between the photoelectric conversion layer and the two electrodes, as necessary. In the photoelectric conversion device, light having a desired wavelength is absorbed in the photoelectric conversion layer to generate an exciton, and then charge separation of the exciton generates a hole and an electron. Thereafter, the hole and the electron move toward each electrode to convert the light into an electric signal. For a purpose of accelerating this process, a method of applying a bias voltage between both the electrodes is commonly used, but one of objects is reducing a leakage current from both the electrodes generated by applying the bias voltage. Accordingly, it can be mentioned that controlling the move of the hole and the electron in the photoelectric conversion device is a key to exhibit characteristic of the photoelectric conversion device.

The organic semiconductor used for each layer of the photoelectric conversion device can be classified into a P-type organic semiconductor and an N-type organic semiconductor. The P-type organic semiconductor is used as a hole transport material, and the N-type organic semiconductor is used as an electron transport material. To control the move of the hole and the electron in the aforementioned photoelectric conversion device, made are various developments of an organic semiconductor having appropriate physical properties such as hole mobility, electron mobility, an energy value of a highest occupied molecular orbital (HOMO), and an energy value of a lowest unoccupied molecular orbital (LUMO). However, the organic semiconductor still has insufficient characteristics, and has not been utilized in commercial practice.

Patent literature 1 proposes a device using an indolocarbazole derivative for the electron blocking layer disposed between the photoelectric conversion layer and the electrode.

Meanwhile, Patent Literature 2 discloses an organic EL device using an indolocarbazole compound substituted with a nitrogen-containing six-membered cyclic structure.

Patent Literature 3 discloses an organic EL device using an indolocarbazole compound substituted with a carbazole structure, but all the above do not specifically describe exhibited excellent characteristics as a material for a photoelectric conversion device for imaging.

### CITATION LIST

### Patent Literature

### Patent Literature 1

JP 2018-85427 (A)

### Patent Literature 2

WO2008/056746

### Patent Literature 3

WO2009/136595

### Non Patent Literature

### Non Patent Literature 1

NHK Science & Technology Research Laboratories R&D No. 132, pp. 4-11 (2012.3)

### Non Patent Literature 2

NHK Science & Technology Research Laboratories R&D No. 174, pp. 4-17 (2019.3)

### Non Patent Literature 3

2019 IEEE International Electron Devices Meeting (IEDM), pp. 16.6.1-16.6.4 (2019)

### SUMMARY OF INVENTION

### Technical Problem

In the use of the photoelectric conversion device for imaging for highly functionalizing a digital camera and a camera for a smartphone and for application for a monitoring camera, a sensor for an automobile, and the like, challenges are further higher sensitivity and higher resolution. In view of such a circumstance, an object of the present invention is to provide a material that achieves higher sensitivity and higher resolution of the photoelectric conversion device for imaging, and a photoelectric conversion device for imaging using the same.

### Solution to Problem

The present inventors have intensively investigated the above problem, and consequently found that using an indolocarbazole compound having a specific substituent having an amine skeleton efficiently proceeds a process of generating a hole and an electron by charge separation of an exciton in a photoelectric conversion layer in a photoelectric conversion device, and a process of moving of the hole and the electron in the photoelectric conversion device. This finding has led to the completion of the present invention. In particular, it has been newly found that using the compound of the present invention controls the charge generation in the photoelectric conversion device and the process of moving to improve a contrast ratio that leads to high sensitivity of the photoelectric conversion device.

The present invention is a material for a photoelectric conversion device for imaging, represented by the following general formula (1) or (2).

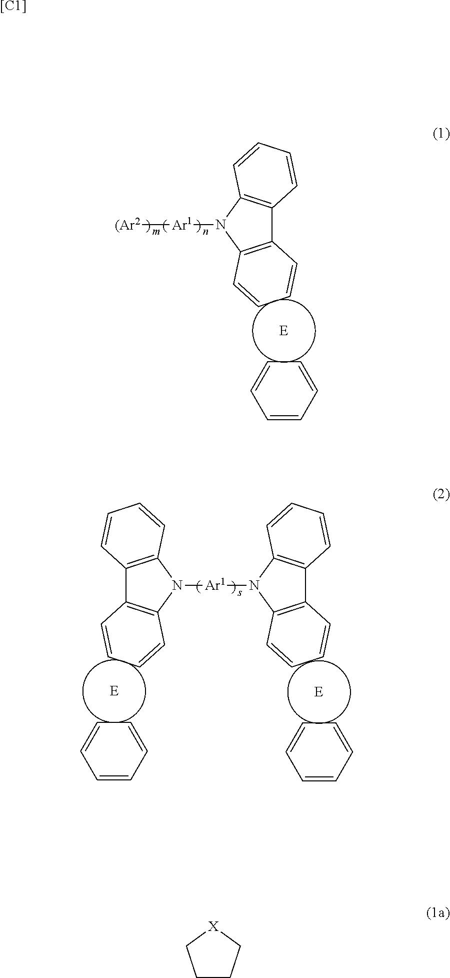

In the general formulae (1) and (2), the ring E independently represents a heterocyclic ring condensed with an adjacent ring at any position and represented by the formula (1a).

Here, X is represented by O, S, C(Ra)₂, or N—(Ar⁵)ₚ—(Ar⁶)_{q}, and preferably represented by O, S, or N—(Ar⁵)ₚ—(Ar⁶)_{q}.

In the general formula (1), Ar¹, Ar², Ar⁵, and Ar⁶ each independently represent a substituted or unsubstituted diarylamino group having 12 to 30 carbon atoms, a substituted or unsubstituted arylheteroarylamino group having 12 to 30 carbon atoms, a substituted or unsubstituted diheteroarylamino group having 12 to 30 carbon atoms, a substituted or unsubstituted aromatic hydrocarbon group having 6 to 30 carbon atoms, or a substituted or unsubstituted heteroaromatic group having 4 to 18 carbon atoms. When Ar¹, Ar², Ar⁵, and Ar⁶ represent a substituted or unsubstituted heteroaromatic group, the number of carbon atoms is preferably 6 to 18. Among these, each of the amino groups in Ar¹, Ar², Ar⁵, and Ar⁶ is optionally condensed as in the formulae (3a) to (3d) described later.

In the general formula (1), when the number of repetition “n” is plural, the number “n” of Ar¹ may be the same as or different from each other. A case of Ar⁵ when the number of repetition “p” is plural is the same as above. When the number of substitution “m” is plural, the number “m” of Ar² may be the same as or different from each other. A case of Ar⁶ when the number of repetition “q” is plural is the same as above.

A case of Ar¹, Ar⁵, and Ar⁶ in the general formula (2) is the same as in the general formula (1). Ar¹, Ar⁵, and Ar⁶ each independently represent a substituted or unsubstituted diarylamino group having 12 to 30 carbon atoms, a substituted or unsubstituted arylheteroarylamino group having 12 to 30 carbon atoms, a substituted or unsubstituted diheteroarylamino group having 12 to 30 carbon atoms, a substituted or unsubstituted aromatic hydrocarbon group having 6 to 30 carbon atoms, or a substituted or unsubstituted heteroaromatic group having 4 to 18 carbon atoms. When Ar¹, Ar⁵, and Ar⁶ represent a substituted or unsubstituted heteroaromatic group, the number of carbon atoms is preferably 6 to 18. Among these, each of the amino groups in Ar¹, Ar², Ar⁵, and Ar⁶ is optionally condensed as in the formulae (3a) to (3d) described later.

In the general formula (2), when the number of repetition “n” is plural, the number “n” of Ar¹ may be the same as or different from each other. A case of Ar⁵ when the number of repetition “p” is plural is the same as above. When the number of repetition “p” is plural, the number “p” of Ar⁶ may be the same as or different from each other.

“n”, “p”, and “s” represent the number of repetition, “n” and “p” independently represent an integer of 0 to 4, and “s” represents an integer of 1 to 4. “m” and “q” represent the number of substitution, and “m” and “q” independently represent an integer of 1 to 3. “n” and “p” preferably represent 0 to 2, and “s” preferably represents 1 to 3. “m” and “q” preferably represent 1 to 2. It is to be noted that when “n” represents 0, “m” represents 1, and when “p” represents 0, “q” represents 1.

Ra each independently represents an alkyl group having 1 to 20 carbon atoms, a substituted or unsubstituted aromatic hydrocarbon group having 6 to 30 carbon atoms, or a substituted or unsubstituted heteroaromatic group having 4 to 18 carbon atoms.

In each of the general formulae (1) and (2), at least one Ar¹, Ar², Ar⁵, or Ar⁶ is represented by a substituted or unsubstituted diarylamino group having 12 to 30 carbon atoms, a substituted or unsubstituted arylheteroarylamino group having 12 to 30 carbon atoms, a substituted or unsubstituted diheteroarylamino group having 12 to 30 carbon atoms, or any one of the following formulae (3a) to (3d) in which the amino group is further condensed. It is to be noted that a case of being represented by a group in which the amino group in Ar¹ or Ar⁵ is further condensed is represented by (3a) or (3b), and a case of being represented by a group in which the amino group in Ar² or Ar⁶ is further condensed is represented by the following formula (3c) or (3d).

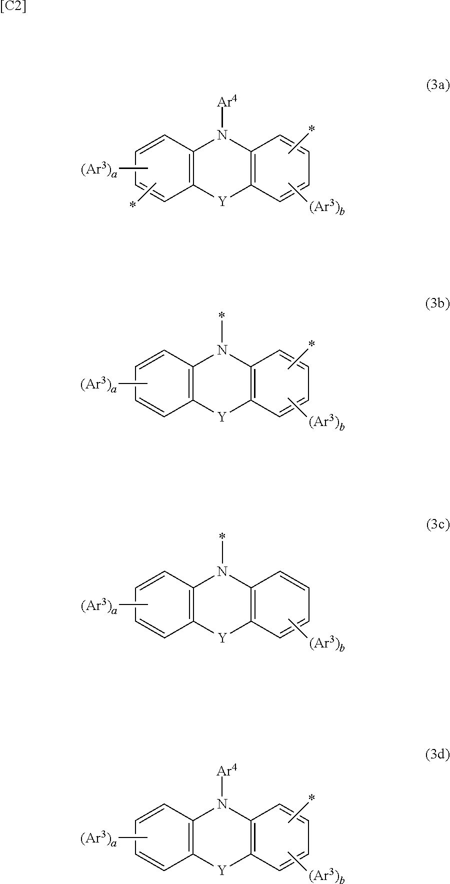

Y is each independently represented by a single bond, Si(Rb)₂, C(Rb)₂, O, S, Se, or N—Rb, and preferably represented by Si(Rb)₂, C(Rb)₂, O, or S.

Rb each independently represents an alkyl group having 1 to 20 carbon atoms, a substituted or unsubstituted aromatic hydrocarbon group having 6 to 30 carbon atoms, or a substituted or unsubstituted heteroaromatic group having 4 to 18 carbon atoms.

Ar³ and Ar⁴ each independently represent a substituted or unsubstituted diarylamino group having 12 to 30 carbon atoms, a substituted or unsubstituted arylheteroarylamino group having 12 to 30 carbon atoms, a substituted or unsubstituted diheteroarylamino group having 12 to 30 carbon atoms, a substituted or unsubstituted aromatic hydrocarbon group having 6 to 30 carbon atoms, or a substituted or unsubstituted heteroaromatic group having 4 to 18 carbon atoms. When Ar³ and Ar⁴ represent a substituted or unsubstituted heteroaromatic group, the number of carbon atoms is preferably 6 to 18.

In the general formulae (1) and (2), at least one of Ar¹, Ar², Ar⁵, and Ar⁶ is preferably represented by a substituted or unsubstituted diarylamino group having 12 to 30 carbon atoms, a substituted or unsubstituted arylheteroarylamino group having 12 to 30 carbon atoms, or a substituted or unsubstituted diheteroarylamino group having 12 to 30 carbon atoms.

Among these, at least one or two of Ar¹, Ar², Ar⁵, and Ar⁶ is preferably represented by a substituted or unsubstituted diarylamino group having 12 to 30 carbon atoms or a substituted or unsubstituted arylheteroarylamino group having 12 to 27 carbon atoms.

Here, in the general formula (1), preferably at least any one, more preferably two, of the following requirement (i), (ii), (iii), (iv), (v), (vi), (vii), or (viii) are satisfied:
(i) in a case of n=2 to 4, at least one pair of Ar¹ adjacent to each other represent phenyl groups to form a biphenyl group;
(ii) Ar¹ and Ar² adjacent to each other represent phenyl groups to form a biphenyl group;
(iii) in a case of p=2 to 4, at least one pair of Ar⁵ adjacent to each other represent phenyl groups to form a biphenyl group;
(iv) Ar⁵ and Ar⁶ adjacent to each other represent phenyl groups to form a biphenyl group;
(v) at least one Ar¹ represents a substituted or unsubstituted diarylamino group having 12 to 30 carbon atoms or a substituted or unsubstituted arylheteroarylamino group having 12 to 27 carbon atoms, and has at least one biphenyl group as an aryl group of the amino group;
(vi) at least one Ar² represents a substituted or unsubstituted diarylamino group having 12 to 30 carbon atoms or a substituted or unsubstituted arylheteroarylamino group having 12 to 27 carbon atoms, and has at least one biphenyl group as an aryl group of the amino group;
(vii) at least one Ar⁵ represents a substituted or unsubstituted diarylamino group having 12 to 30 carbon atoms or a substituted or unsubstituted arylheteroarylamino group having 12 to 27 carbon atoms, and has at least one biphenyl group as an aryl group of the amino group; and
(viii) at least one Ar⁶ represents a substituted or unsubstituted diarylamino group having 12 to 30 carbon atoms or a substituted or unsubstituted arylheteroarylamino group having 12 to 27 carbon atoms, and an aryl group of the amino group has at least one biphenyl group.

At least one or two of Ar¹, Ar², Ar⁵, and Ar⁶ is preferably represented by any one of the formulae (3a) to (3d). It is to be noted that Ar¹ or Ar⁵ is selected from the formula (3a) or (3b), and Ar² or Ar⁶ is selected from the formula (3c) or (3d).

Further at least one of Ar¹, Ar², Ar⁵, or Ar⁶ is preferably represented by a carbazolyl group, a dibenzofuran group, or a dibenzothiophene group.

“a” and “b” represent the number of substitution, and each independently represent 0 to 3. “a” and “b” preferably represents 0 to 2. It is to be noted that “*” in the formulae (3a) to (3d) represents a bonding position with N on the pyrrole ring in the general formula (1) or a bonding position with adjacent Ar¹, Ar², Ar⁵, or Ar⁶.

In the material for a photoelectric conversion device, preferably satisfied is any one of requirements that: an energy level of highest occupied molecular orbital (HOMO) obtained by structural optimization calculation with density functional calculation B3LYP/6-31G(d) is −4.5 eV or lower; an energy level of lowest unoccupied molecular orbital (LUMO) obtained by the structural optimization calculation is −2.5 eV or higher; the material has a hole mobility of 1×10⁻⁶ cm²/Vs or more; or the material is amorphous.

The material for a photoelectric conversion device may be used as a hole transport material of a photoelectric conversion device for imaging.

The present invention is a photoelectric conversion device for imaging, comprising a photoelectric conversion layer and an electron blocking layer between two electrodes, wherein at least one layer of the photoelectric conversion layer or the electron blocking layer contains the above material for a photoelectric conversion device.

The above material for a photoelectric conversion device is preferably contained in an electron blocking layer or a photoelectric conversion layer of the photoelectric conversion device, and in this case, preferably contained as a hole transport material. When the material for a photoelectric conversion device is contained in the electron blocking layer, the photoelectric conversion layer preferably contains an electron transport material or a fullerene derivative.

### Advantageous Effect of Invention

The material for a photoelectric conversion device for imaging of the present invention can achieve appropriate move of the hole and the electron in the photoelectric conversion device, and consequently enables to reduce a leakage current generated by applying a bias voltage during the conversion of light into electric energy. As a result, a photoelectric conversion device that achieves a low dark current value and a high contrast ratio can be obtained. The material of the present invention is useful as a material for a photoelectric conversion device for a photoelectric-converting film-stacked imaging device.

### BRIEF DESCRIPTION OF DRAWING

FIG. 1 is a sectional schematic view illustrating a structure example of a photoelectric conversion device for imaging.

### DESCRIPTION OF EMBODIMENTS

A photoelectric conversion device for imaging of the present invention comprises at least one organic layer between two electrodes. This organic layer contains the material for a photoelectric conversion device for imaging represented by any one of the general formula (1) or (2). Specifically, in a photoelectric conversion device for imaging comprising a photoelectric conversion layer and an electron blocking layer between two electrodes, at least one layer of the photoelectric conversion layer and the electron blocking layer contains the material for a photoelectric conversion device for imaging represented by any one of the general formula (1) or (2).

Hereinafter, the material for a photoelectric conversion device for imaging represented by any one of the general formula (1) or (2) is also referred to as “material for a photoelectric conversion device”, “material of the present invention”, or “compound represented by the general formula (1) or (2)”.

The compound represented by the general formula (1) or (2) will be described hereinafter.

In the general formulae (1) and (2), the ring E each independently represents a heterocyclic ring condensed with an adjacent ring at any position and represented by the formula (1a). The material of the invention is preferably represented by the general formula (1).

X is represented by O, S, C(Ra)₂, or N—(Ar⁵)ₚ—(Ar⁶)_{q}, and preferably represented by O, S, or N—(Ar⁵)ₚ—(Ar⁶)_{q}.

“n”, “p”, and “s” represent the number of repetition, “n” and “p” independently represent an integer of 0 to 4, and “s” represents an integer of 1 to 4. “n” preferably represents 0 to 2, and “s” preferably represents 1 to 3. “m” and “q” independently represent the number of substitution, and “m” and “q” independently represent an integer of 1 to 3. “m” and “q” preferably represent 1 to 2. It is to be noted that when “n” represents 0, “m” represents 1, and when “p” represents 0, “q” represents 1.

Ar¹, Ar², Ar⁵, and Ar⁶ each independently represent a substituted or unsubstituted diarylamino group having 12 to 30 carbon atoms, a substituted or unsubstituted arylheteroarylamino group having 12 to 30 carbon atoms, a substituted or unsubstituted diheteroarylamino group having 12 to 30 carbon atoms, a substituted or unsubstituted aromatic hydrocarbon group having 6 to 30 carbon atoms, or a substituted or unsubstituted heteroaromatic group having 4 to 18 carbon atoms. It is to be noted that at least one of Ar¹, Ar², Ar⁵, or Ar⁶, preferably at least two of Ar¹, Ar², Ar⁵, and Ar⁶, are represented by a substituted or unsubstituted diarylamino group having 12 to 30 carbon atoms, a substituted or unsubstituted arylheteroarylamino group having 12 to 30 carbon atoms, a substituted or unsubstituted diheteroarylamino group having 12 to 30 carbon atoms, or any one of the formulae (3a) to (3d) in which the amino group is further condensed. The case of being represented by a group in which the amino group in Ar¹ or Ar⁵ is further condensed is represented by the formula (3a) or (3b). The case of being represented by a group in which the amino group in Ar² or Ar⁶ is further condensed is represented by the formula (3c) or (3d). In the general formula (1), when a plurality of Ar¹ are present, when a plurality of Ar² are present, when a plurality of Ar⁵ are present, or when a plurality of Ar⁶ are present, the consideration is the same as noted above. Ar¹, Ar⁵, and Ar⁶ in the general formula (2) are similar to the above.

The general formula (1) preferably has a biphenyl group. The biphenyl group may be bonded at any one of an ortho-, meta-, or para-position, but is preferably para-biphenyl. Specifically, in the general formula (1), preferably at least any one, more preferably at least two, of the following requirement (i), (ii), (iii), (iv), (v), (vi), (vii), or (viii) are satisfied:
(i) in a case of n=2 to 4, at least one pair of Ar¹ adjacent to each other represent phenyl groups to form a biphenyl group;
(ii) Ar¹ and Ar² adjacent to each other represent phenyl groups to form a biphenyl group;
(iii) in a case of p=2 to 4, at least one pair of Ar⁵ adjacent to each other represent phenyl groups to form a biphenyl group;
(iv) Ar⁵ and Ar⁶ adjacent to each other represent phenyl groups to form a biphenyl group;
(v) at least one Ar¹ represents a substituted or unsubstituted diarylamino group having 12 to 30 carbon atoms or a substituted or unsubstituted arylheteroarylamino group having 12 to 27 carbon atoms, and has at least one biphenyl group as an aryl group of the amino group;
(vi) at least one Ar² represents a substituted or unsubstituted diarylamino group having 12 to 30 carbon atoms or a substituted or unsubstituted arylheteroarylamino group having 12 to 27 carbon atoms, and has at least one biphenyl group as an aryl group of the amino group;
(vii) at least one Ar⁵ represents a substituted or unsubstituted diarylamino group having 12 to 30 carbon atoms or a substituted or unsubstituted arylheteroarylamino group having 12 to 27 carbon atoms, and has at least one biphenyl group as an aryl group of the amino group; and
(viii) at least one Ar⁶ represents a substituted or unsubstituted diarylamino group having 12 to 30 carbon atoms or a substituted or unsubstituted arylheteroarylamino group having 12 to 27 carbon atoms, and an aryl group of the amino group has at least one biphenyl group.

The compounds satisfying the requirements (i) and (iii) are, for example, (B1) and (B2), the compounds satisfying the requirements (ii) and (iv) are, for example, (B40) and (B102), the compounds satisfying the requirements (v) and (vii) are, for example, (B41) and (B103), and the compounds satisfying the requirements (vi) and (viii) are, for example, (B29) and (B104), but the compounds are not limited thereto. The compounds satisfying at least any one requirement (i), (ii), (iii), (iv), (v), (vi), (vii), or (viii) are, for example, (B1) to (B5), (B25) to (B30), (B31), (B32), (B37), (B38), (B40), (B41), (B45) to (B49), (B50) to (B52), (B59), (B60), (B62), (B63), (B66), (B69) to (B74), (B75), (B76), (B81), (B82), (B84), (B85), (B89), (B90), (B96), (B97), or (B102) to (B104). The compounds satisfying at least any two requirements (i), (ii), (iii), (iv), (v), (vi), (vii), or (viii) are, for example, (B1) to (B5), (B21), (B22), (B29) to (B30), (B49), (B73), (B74), or (B102) to (B104). The compounds, however, are not limited thereto.

Specific examples of the unsubstituted diarylamino group having 12 to 30 carbon atoms, the unsubstituted arylheteroarylamino group having 12 to 30 carbon atoms, or the unsubstituted diheteroarylamino group having 12 to 30 carbon atoms include diphenylamino, dibiphenylamino, phenylbiphenylamino, phenylterphenylamino, biphenylterphenylamino, naphthylphenylamino, dinaphthylamino, dianthracenylamino, diphenanthrenylamino, phenyltriphenylenylamino, biphenyltriphenylenylamino, phenylcarbazolylphenylamino, phenylcarbazolylbiphenylamino, biphenylcarbazolylphenylamino, bisphenylcarbazolylamino, dibenzofuranylphenylamino, dibenzofuranylbiphenylamino, or bisdibenzofuranylamino. Preferable examples thereof include diphenylamino, dibiphenylamino, phenylbiphenylamino, naphthylphenylamino, dinaphthylamino, phenylcarbazolylphenylamino, phenylcarbazolylbiphenylamino, dibenzofuranylphenylamino, or dibenzofuranylbiphenylamino. More preferable examples thereof include diphenylamino, phenylbiphenylamino, carbazolylphenylamino, carbazolylbiphenylamino, dibenzofuranylphenylamino, or dibenzofuranylbiphenylamino. The aryl group constituting the above amino groups is preferably an aryl group having 6 to 18 carbon atoms, and the heteroaryl group is preferably a heteroaryl group having 6 to 15 carbon atoms. The number of carbon atoms of these amino groups is preferably 12 to 27. A heteroatom in the heteroaryl group is preferably N, S, or O.

In the present specification, when the diarylamino group, the arylheteroarylamino group, and the diheteroarylamino group have two bonds such as Ar¹, N of the amino group and carbon of the aryl group or the heteroaryl group are the bonding positions.

Examples of the unsubstituted aromatic hydrocarbon compound having 6 to 30 carbon atoms include a group generated from: monocyclic aromatic hydrocarbons, such as benzene; bicyclic aromatic hydrocarbons, such as naphthalene; tricyclic aromatic hydrocarbons, such as indacene, biphenylene, phenalene, anthracene, phenanthrene, and fluorene; tetracyclic aromatic hydrocarbons, such as fluoranthene, acephenanthrylene, aceanthrylene, triphenylene, pyrene, chrysene, tetraphene, tetracene, and pleiadene; pentacyclic aromatic hydrocarbons, such as picene, perylene, pentaphene, pentacene, tetraphenylene, and naphthoanthracene; and the like. The unsubstituted aromatic hydrocarbon compound is preferably a group generated from benzene, naphthalene, anthracene, phenanthrene, triphenylene, or pyrene, and more preferably a group generated from benzene, naphthalene, anthracene, or phenanthrene.

Examples of the unsubstituted aromatic heterocyclic group having 4 to 18 carbon atoms include a group generated from: nitrogen-containing aromatic compounds having a pyrrole ring, such as pyrrole, pyrrolopyrrole, indole, isoindole, pyrroloisoindole, and carboline; thiophene, benzothiophene, dibenzothiophene, furan, benzofuran, dibenzofuran, carbazole, phenylcarbazole, indolocarbazole, pyridine, pyrimidine, quinoline, isoquinoline, quinazoline, quinoxaline, or the like. The unsubstituted heteroaromatic group is preferably a group generated from thiophene, benzothiophene, dibenzothiophene, furan, benzofuran, dibenzofuran, carbazole, phenylcarbazole, or indolocarbazole, and more preferably a group generated from dibenzothiophene, dibenzofuran, carbazole, or phenylcarbazole. Note that, when Ar¹, Ar², Ar⁵, and Ar⁶ represent a substituted or unsubstituted heteroaromatic group, the number of carbon atoms is preferably 6 to 18. Among at least one of Ar¹, Ar², Ar⁵, or Ar⁶, further at least one of them is preferably represented by a dibenzothiophene group, a dibenzofuran group, or a carbazolyl group.

Examples of the substituent herein include a deuterium, a cyano group, or an alkyl group having 1 to 20 carbon atoms.

When the substituent is an alkyl group having 1 to 20 carbon atoms, the alkyl group may be any of a linear, branched, or cyclic alkyl group, and is preferably a linear, branched, or cyclic alkyl group having 1 to 10 carbon atoms. Specific examples thereof include: linear saturated hydrocarbon groups, such as a methyl group, an ethyl group, a n-propyl group, a n-butyl group, a n-pentyl group, a n-hexyl group, a n-octyl group, a n-dodecyl group, a n-tetradecyl group, and a n-octadecyl group; branched saturated hydrocarbon groups, such as an isopropyl group, an isobutyl group, a tert-butyl group, a neopentyl group, a 2-ethylhexyl group, and a 2-hexyloctyl group; and saturated alicyclic hydrocarbon groups, such as a cyclopentyl group, a cyclohexyl group, a cyclooctyl group, a 4-butylcyclohexyl group, and a 4-dodecylcyclohexyl group.

In the present invention, the substituent is bonded to a carbon atom or a heteroatom that constitute the aromatic ring.

Ar³ and Ar⁴ each independently represent a substituted or unsubstituted diarylamino group having 12 to 30 carbon atoms, a substituted or unsubstituted arylheteroarylamino group having 12 to 30 carbon atoms, a substituted or unsubstituted diheteroarylamino group having 12 to 30 carbon atoms, a substituted or unsubstituted aromatic hydrocarbon group having 6 to 30 carbon atoms, or a substituted or unsubstituted heteroaromatic group having 4 to 18 carbon atoms. Examples of the unsubstituted diarylamino group having 12 to 30 carbon atoms, arylheteroarylamino group having 12 to 30 carbon atoms, diheteroarylamino group having 12 to 30 carbon atoms, aromatic hydrocarbon compound having 6 to 30 carbon atoms, and heteroaromatic group having 4 to 18 carbon atoms are the same as those described in Ar¹, Ar², Ar⁵, and Ar⁶. Preferable is benzene, naphthalene, anthracene, phenanthrene, dibenzothiophene, dibenzofuran, carbazole, or phenylcarbazole. Note that, when Ar³ and Ar⁴ represent a substituted or unsubstituted heteroaromatic group, the number of carbon atoms is preferably 6 to 18.

“a” and “b” represent the number of substitution and each independently represent 0 to 3, and preferably represent 0 to 2.

Y is each independently represented by a single bond, Si(Rb)₂, C(Rb)₂, O, S, Se, or N—Rb, and preferably represented by Si(Rb)₂, C(Rb)₂, O, or S.

Ra and Rb each independently represent an alkyl group having 1 to 20 carbon atoms, a substituted or unsubstituted aromatic hydrocarbon group having 6 to 30 carbon atoms, or a substituted or unsubstituted heteroaromatic group having 4 to 18 carbon atoms. Examples of the unsubstituted alkyl group having 1 to 20 carbon atoms are the same as those described as the substituent, and examples of the unsubstituted aromatic hydrocarbon group having 6 to 30 carbon atoms and the unsubstituted heteroaromatic group having 4 to 18 carbon atoms are the same as those described in Ar¹, Ar², Ar⁵, and Ar⁶. Ra and Rb preferably represent an alkyl group having 1 to 10 carbon atoms, a substituted or unsubstituted aromatic hydrocarbon group having 6 to 18 carbon atoms, or a substituted or unsubstituted heteroaromatic group having 6 to 18 carbon atoms.

Preferable specific examples of the material for a photoelectric conversion device represented by the general formula (1) or the general formula (2) of the present invention will be described below, but the material is not limited thereto.

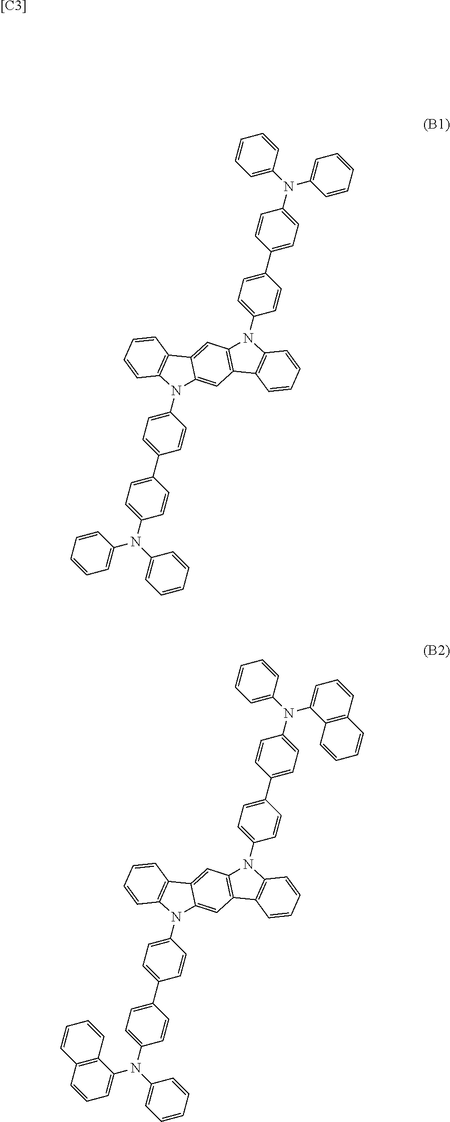

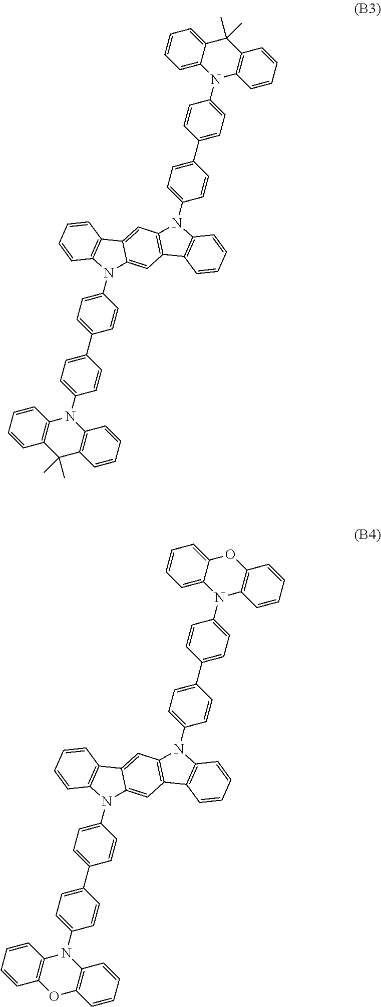

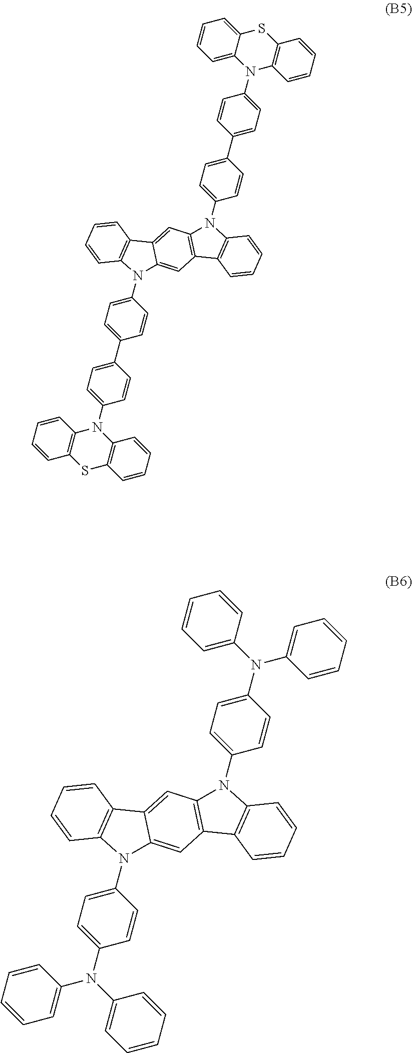

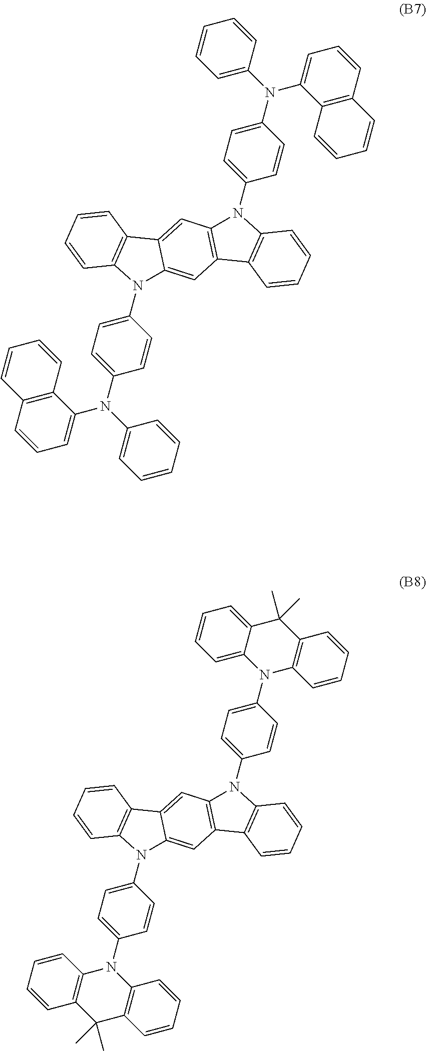

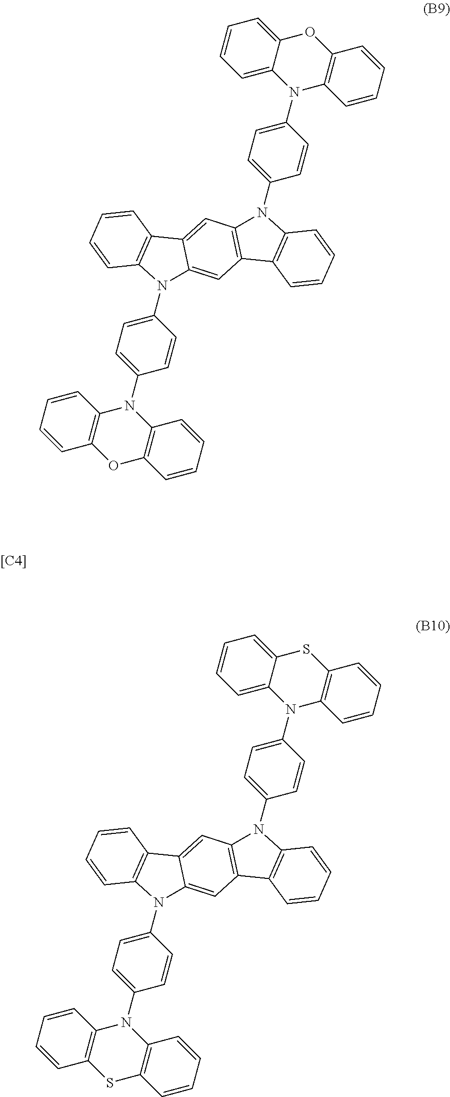

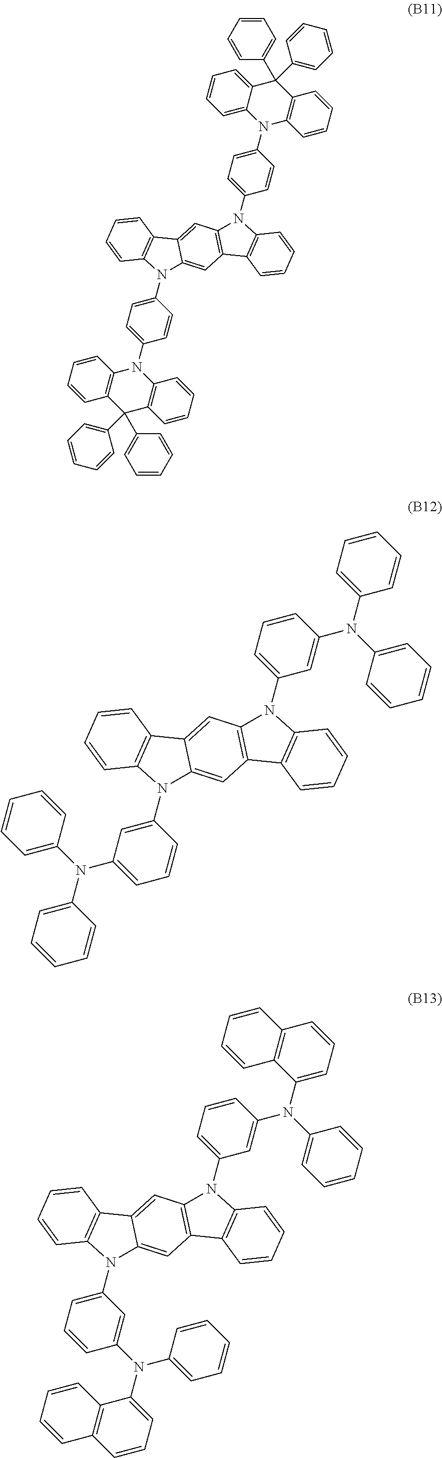

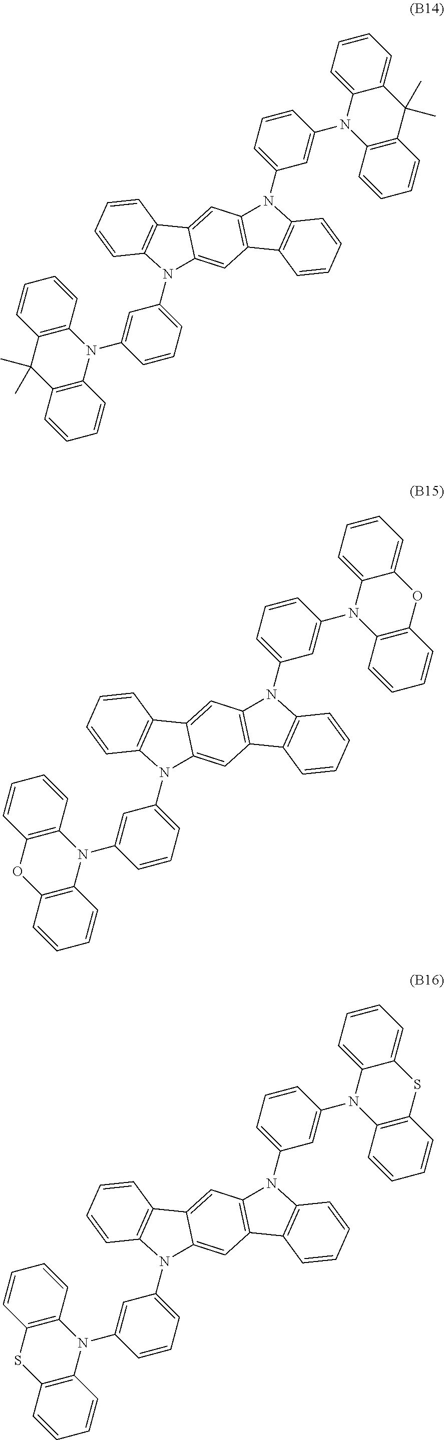

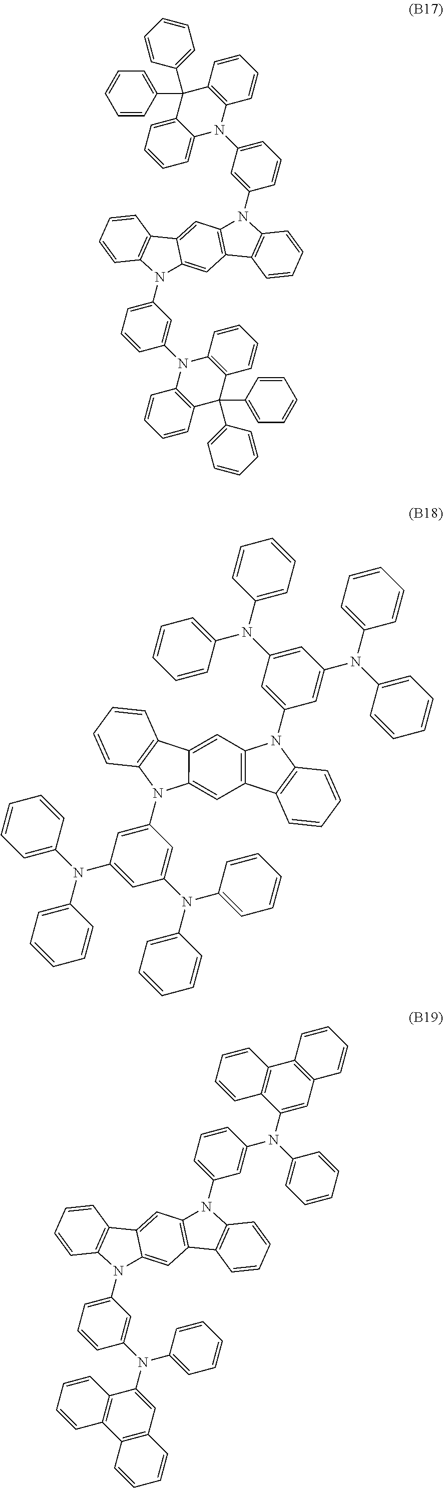

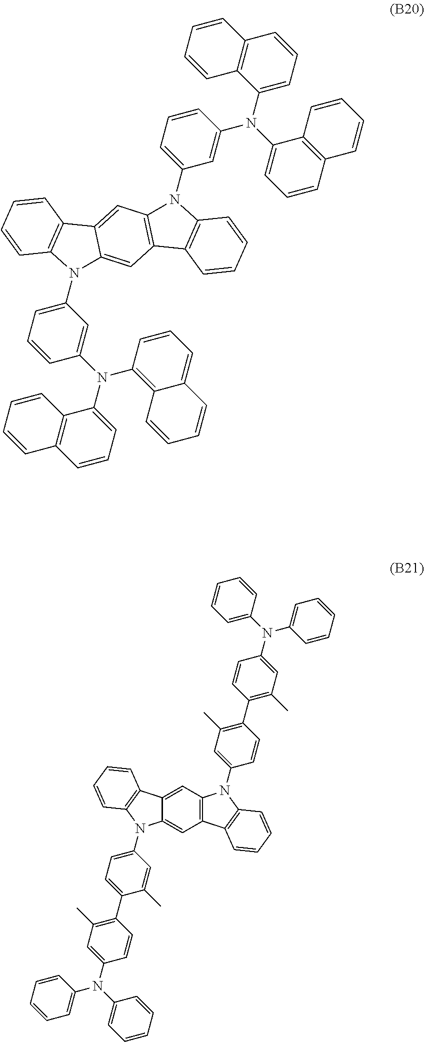

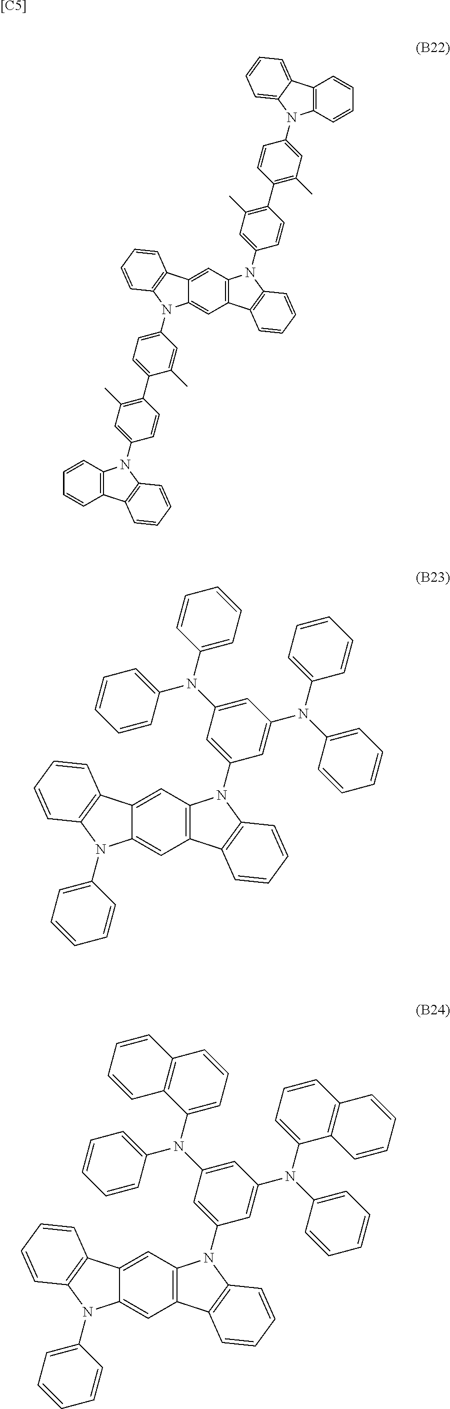

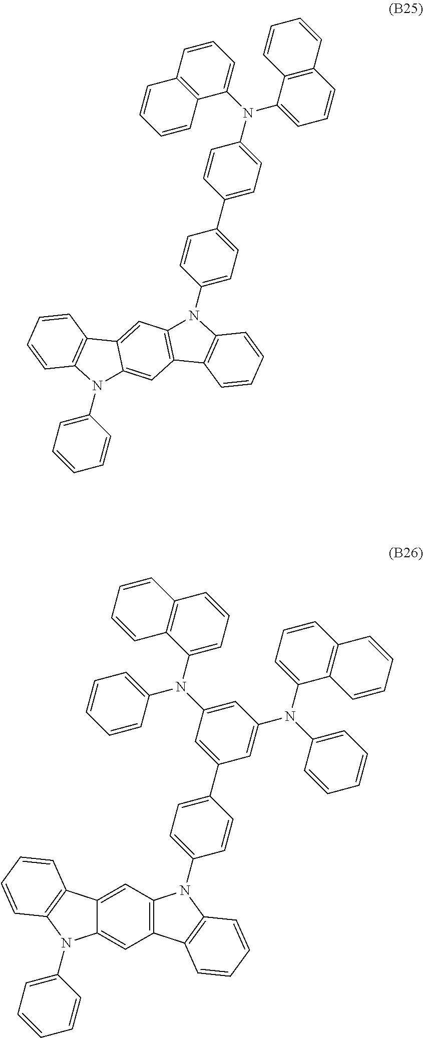

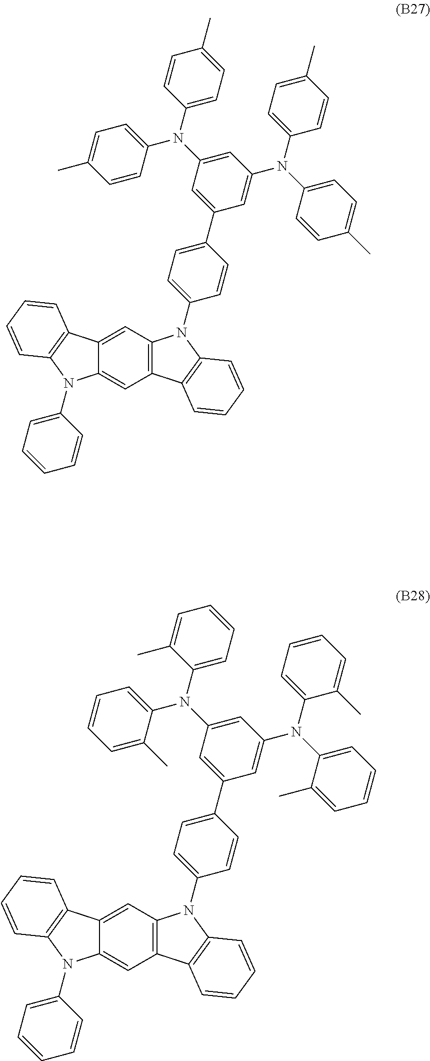

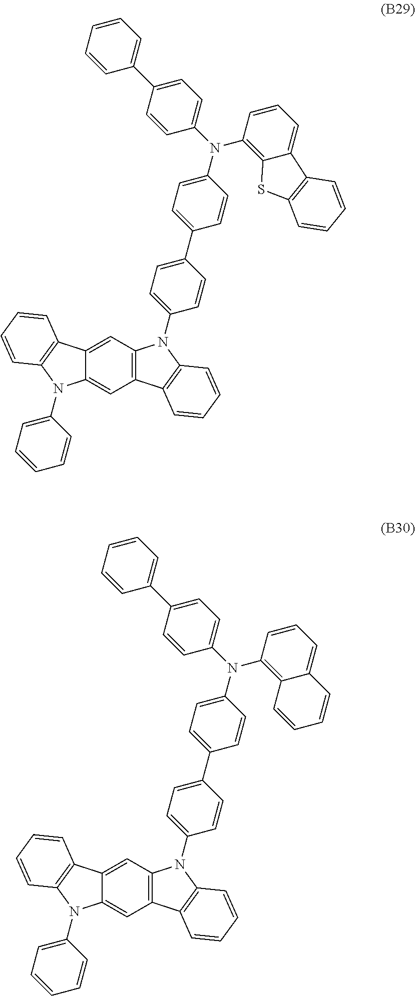

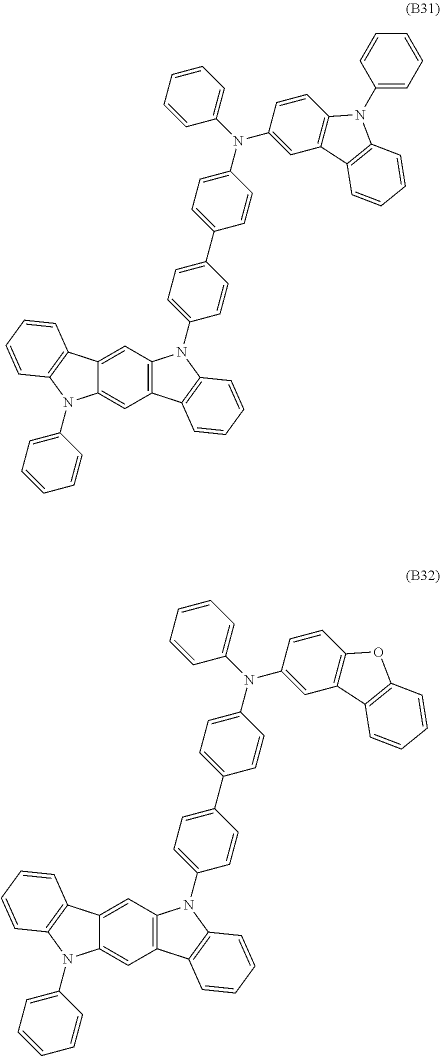

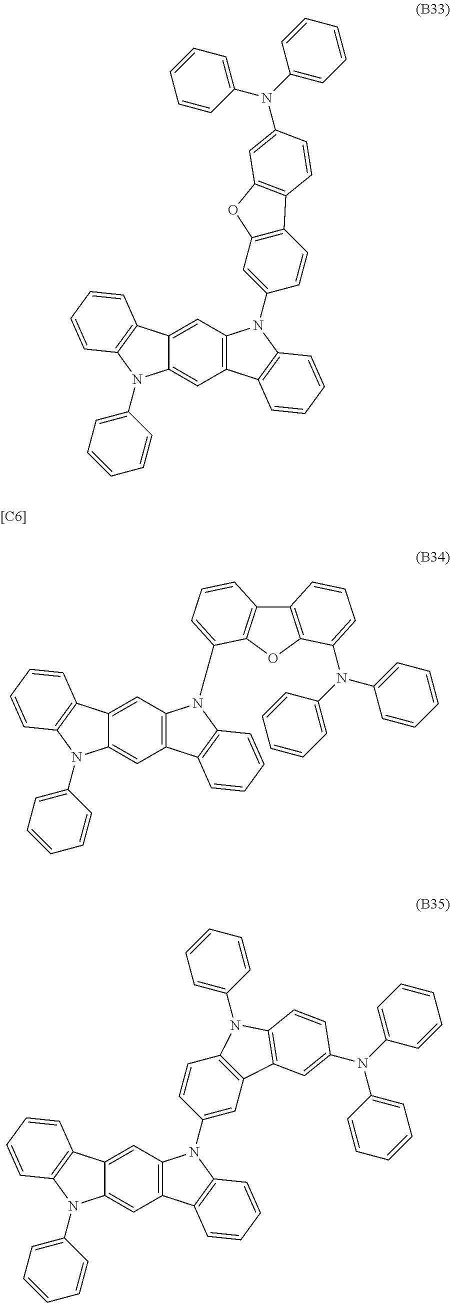

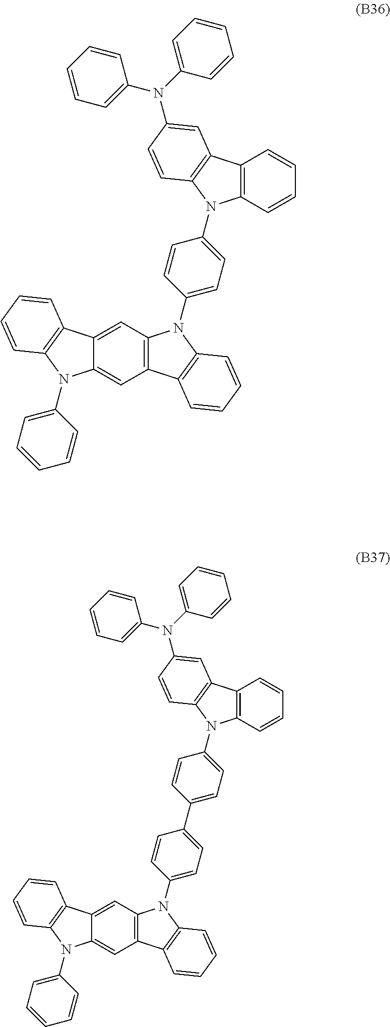

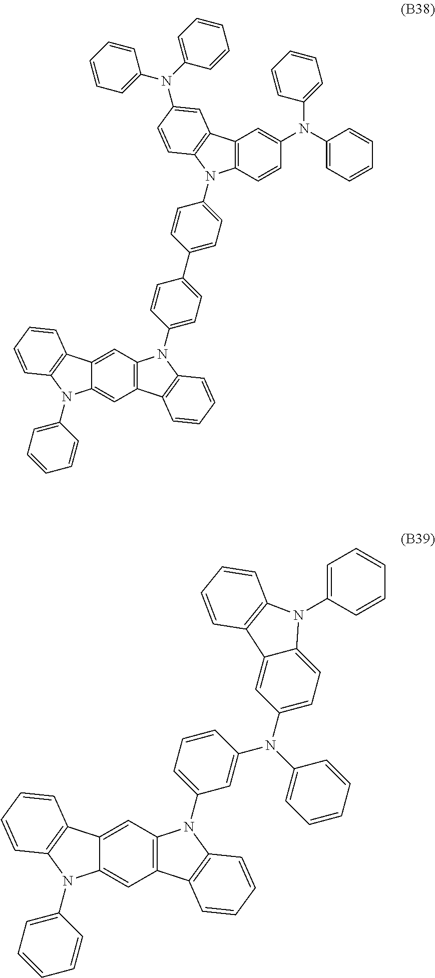

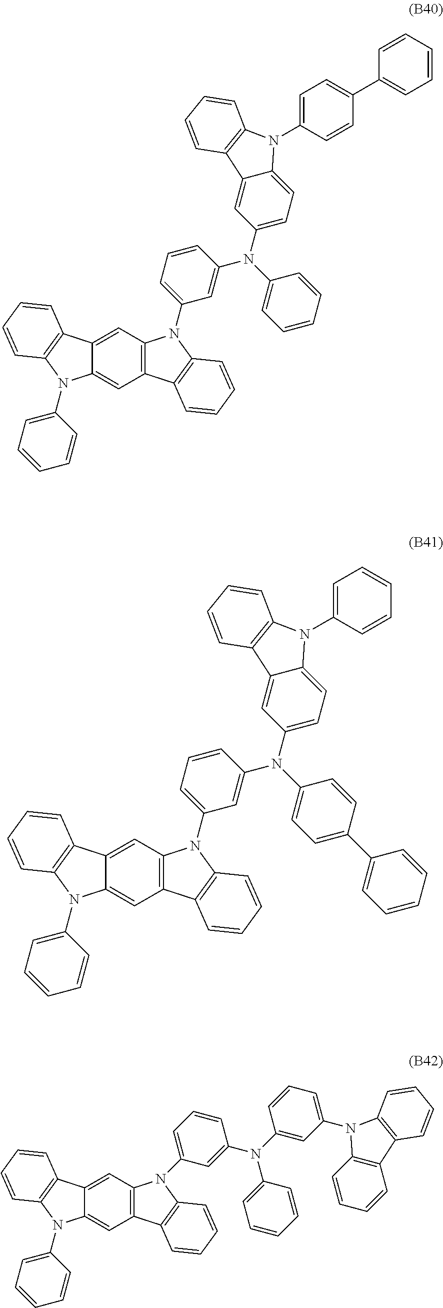

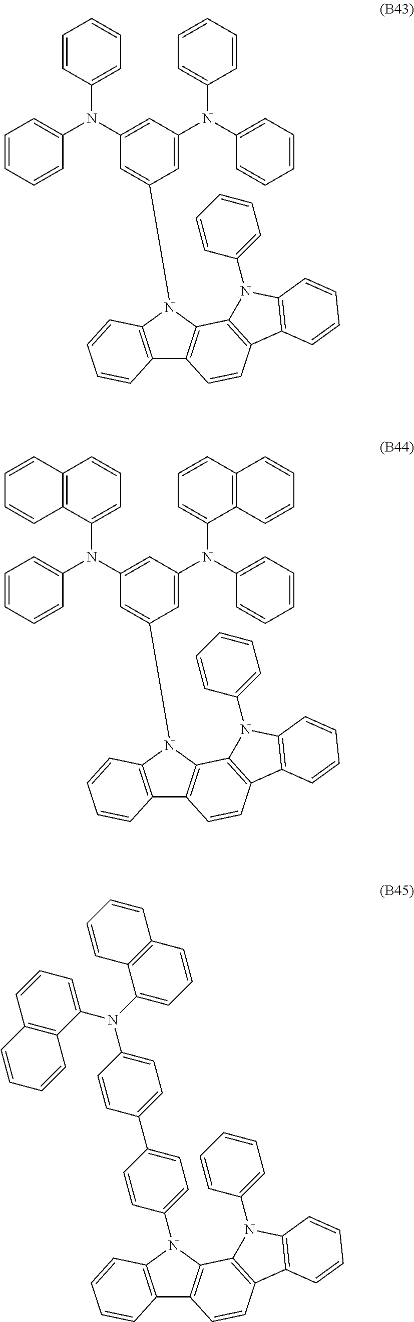

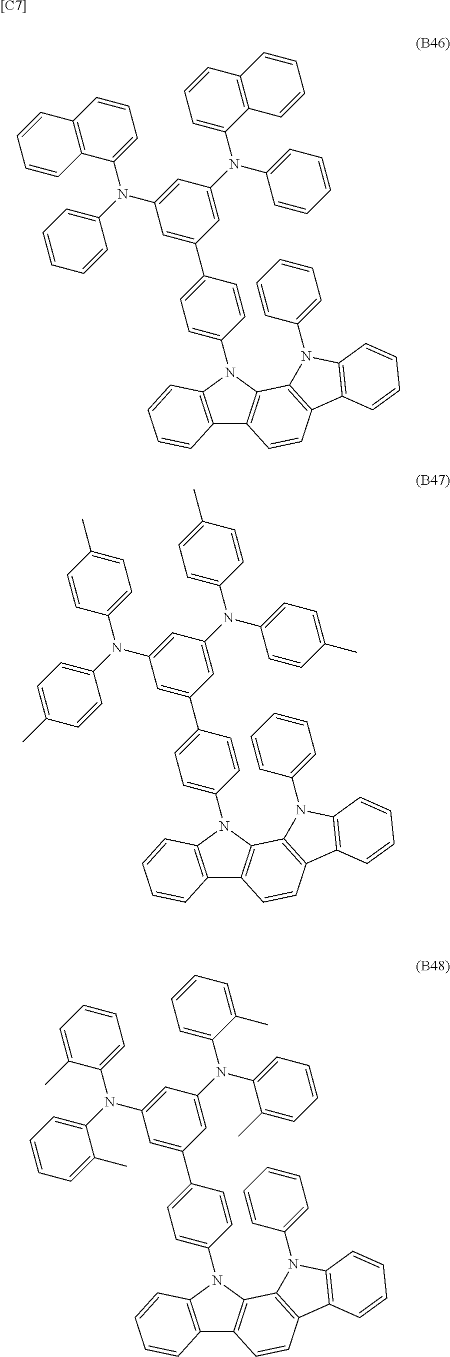

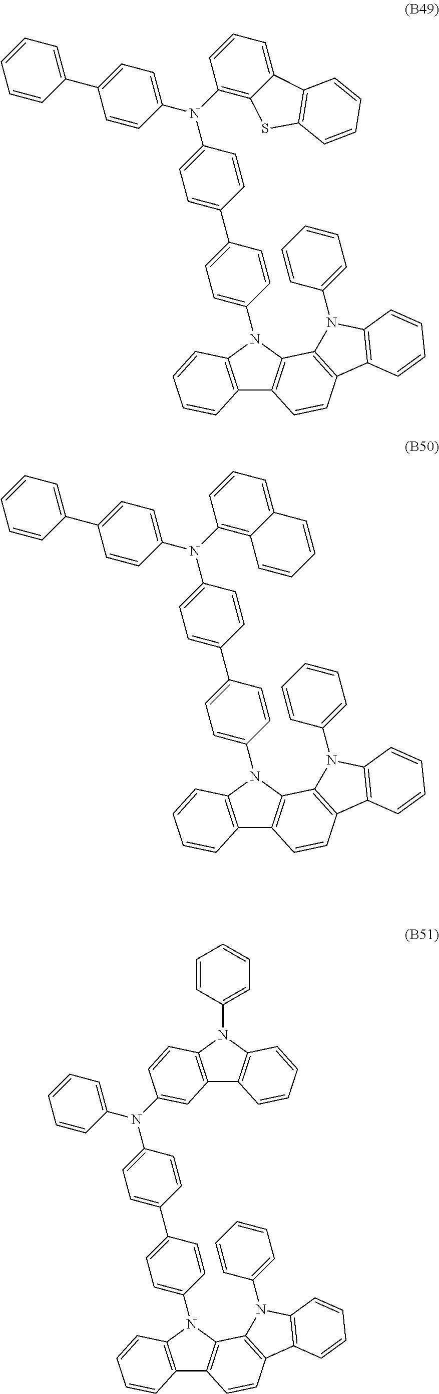

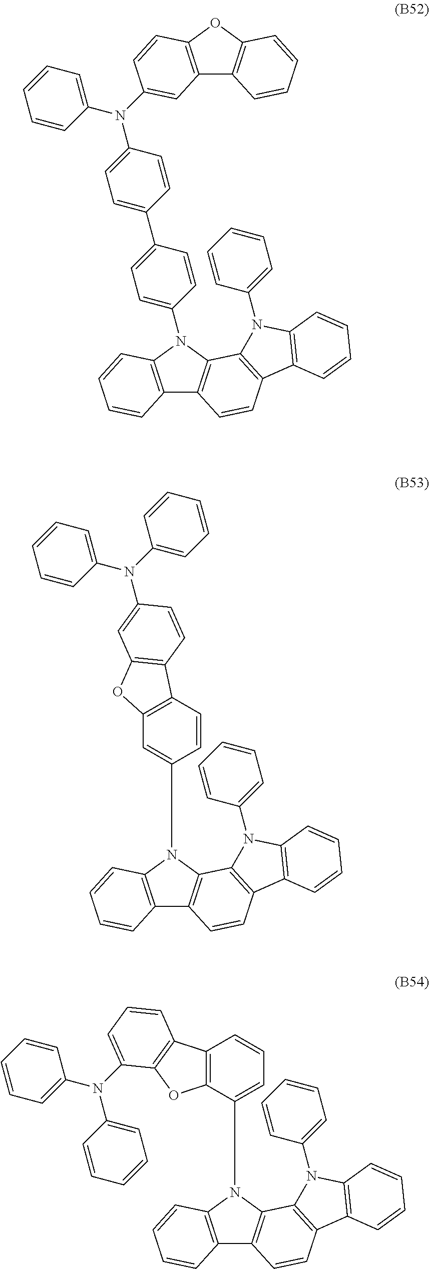

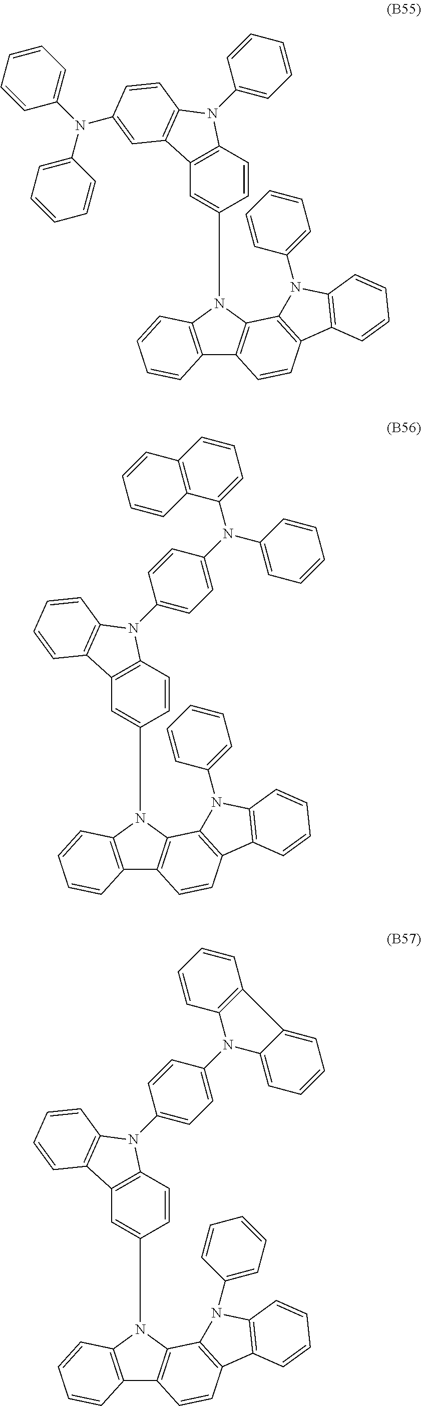

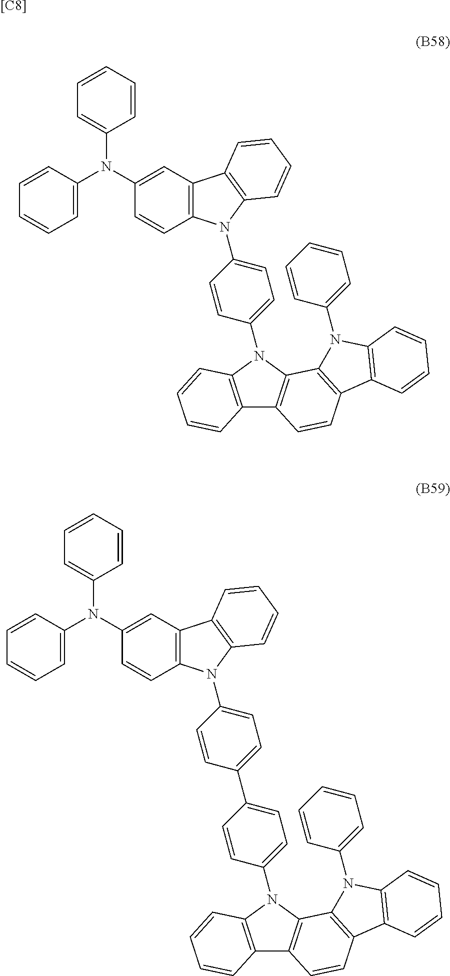

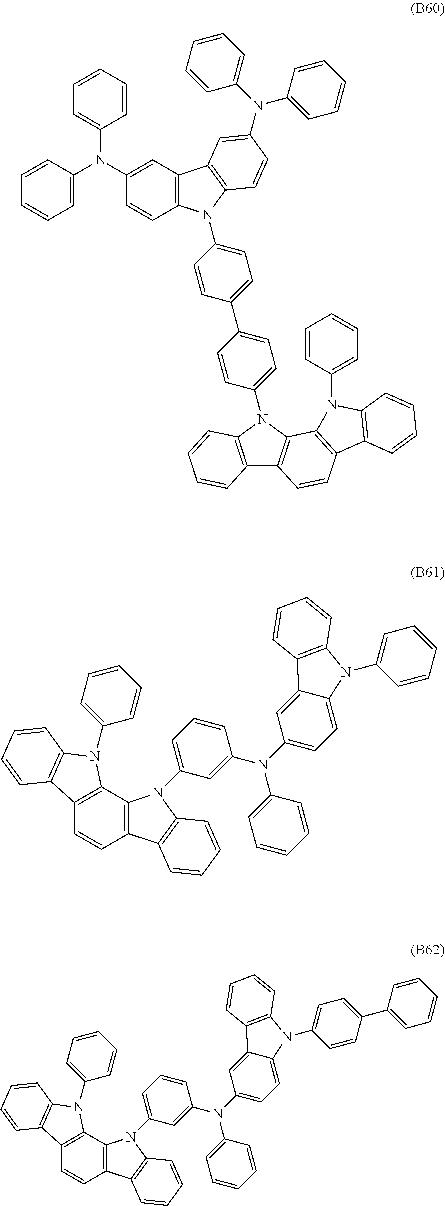

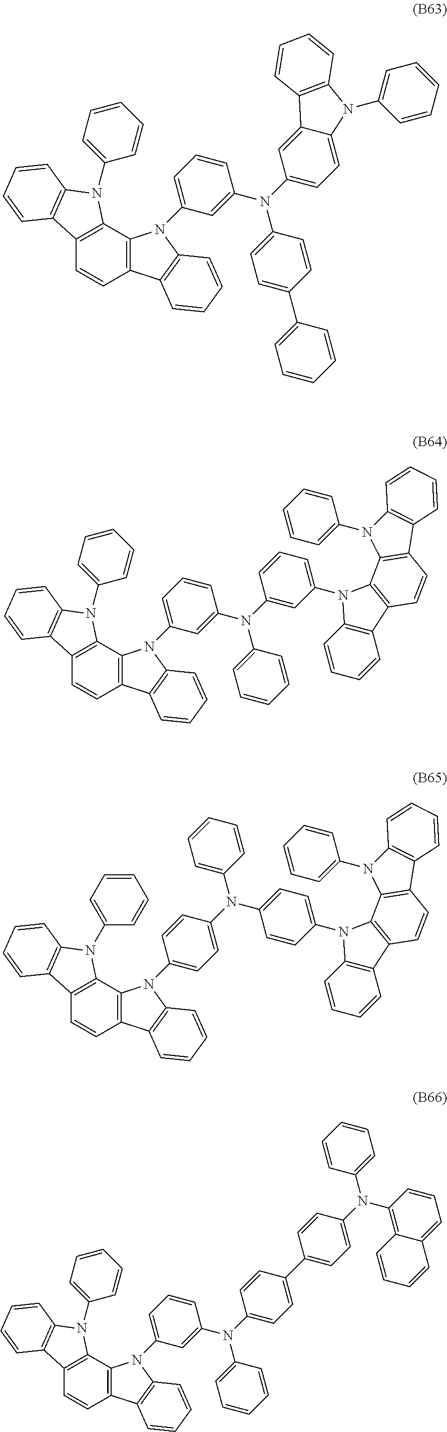

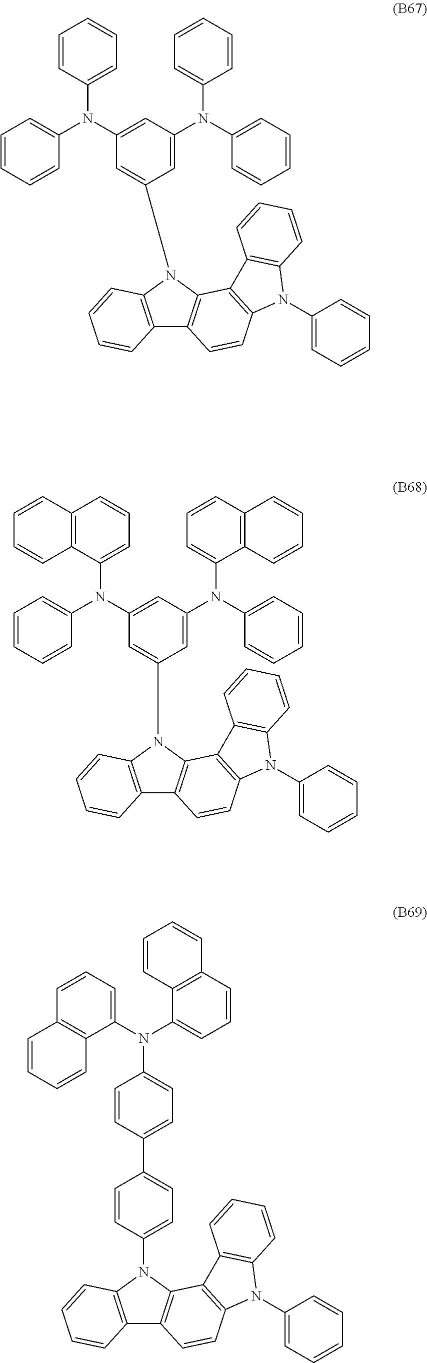

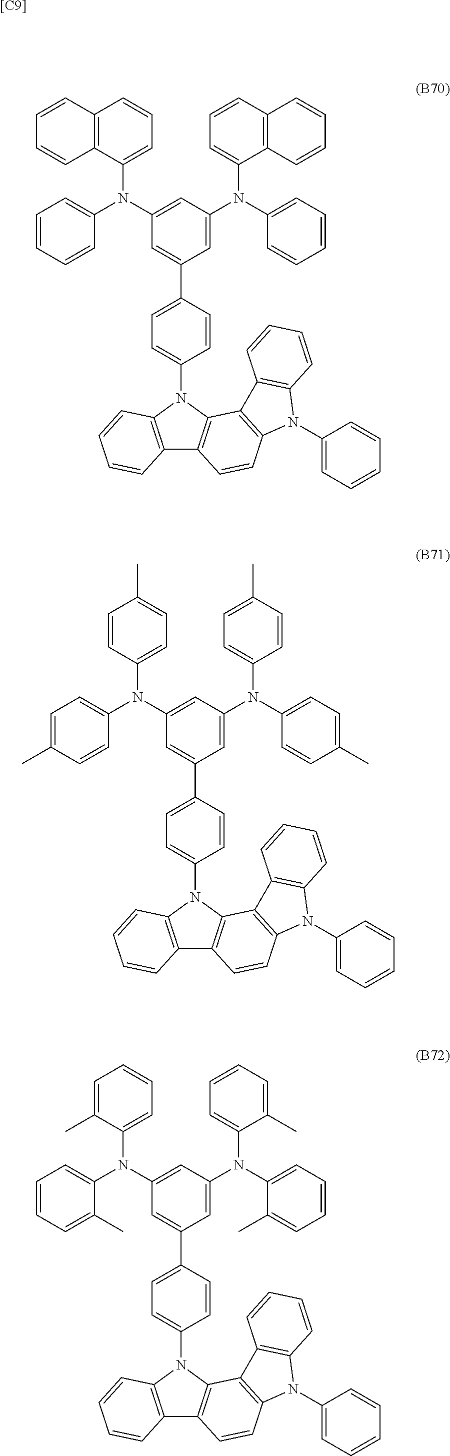

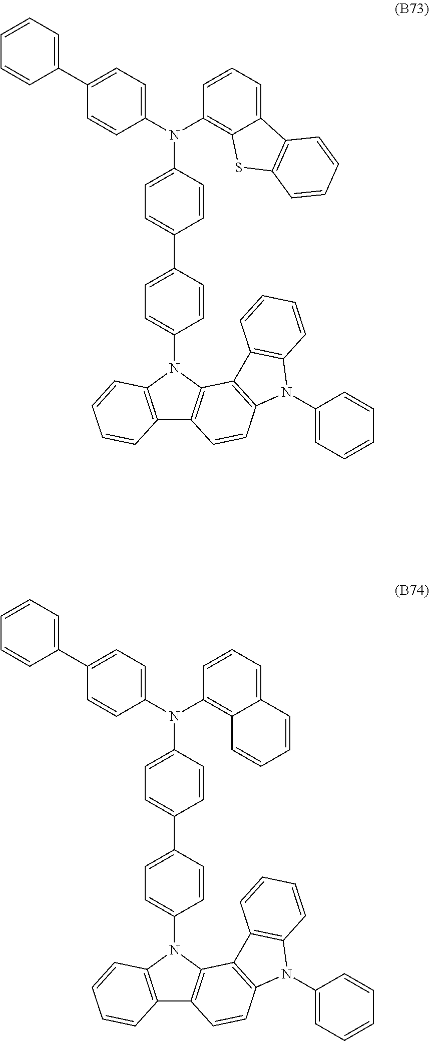

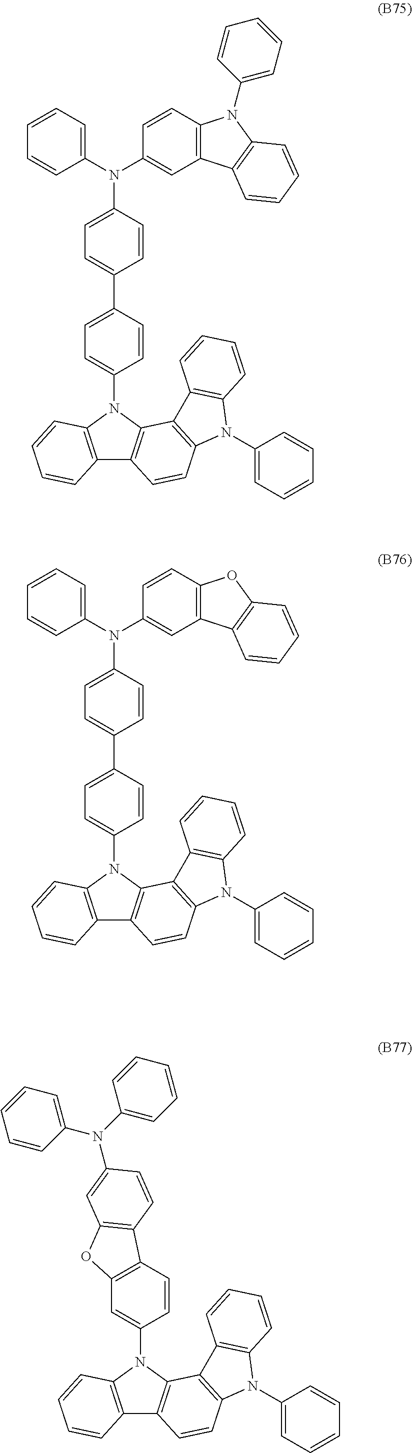

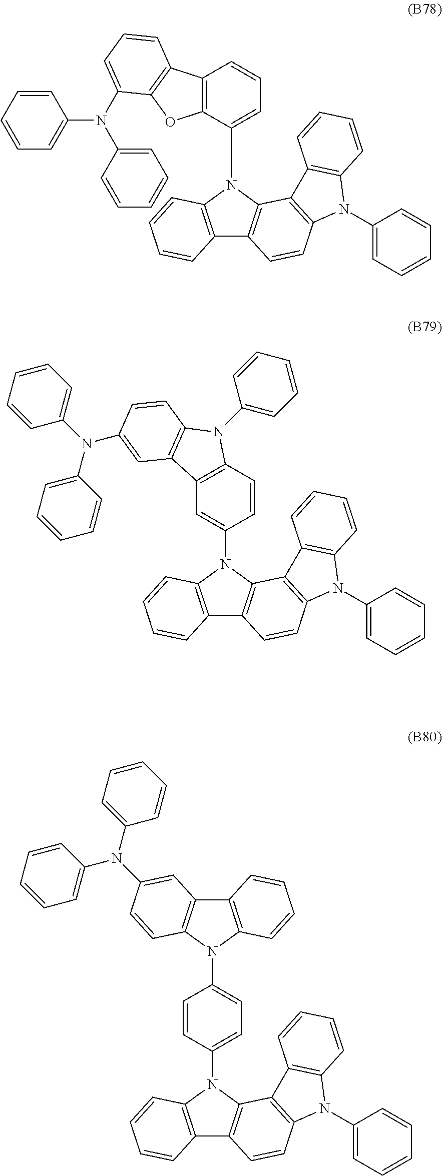

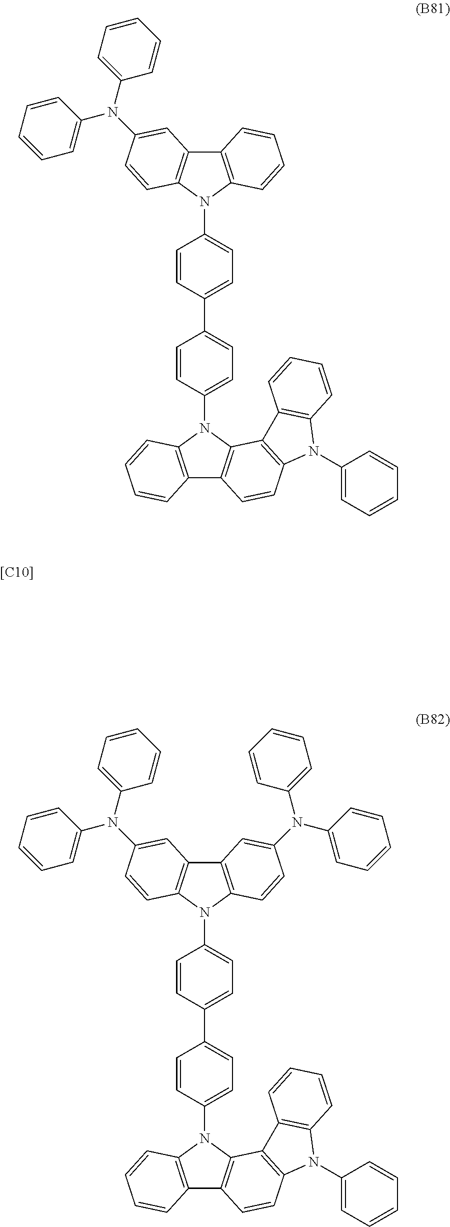

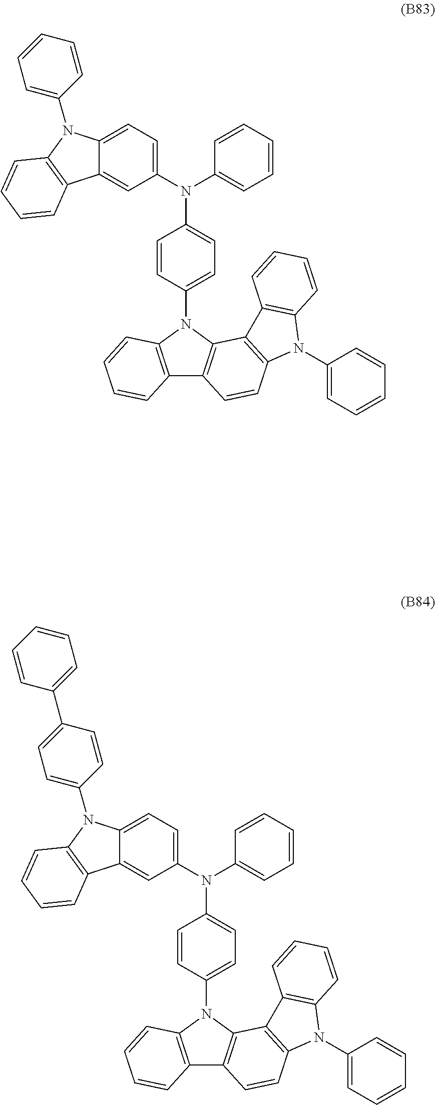

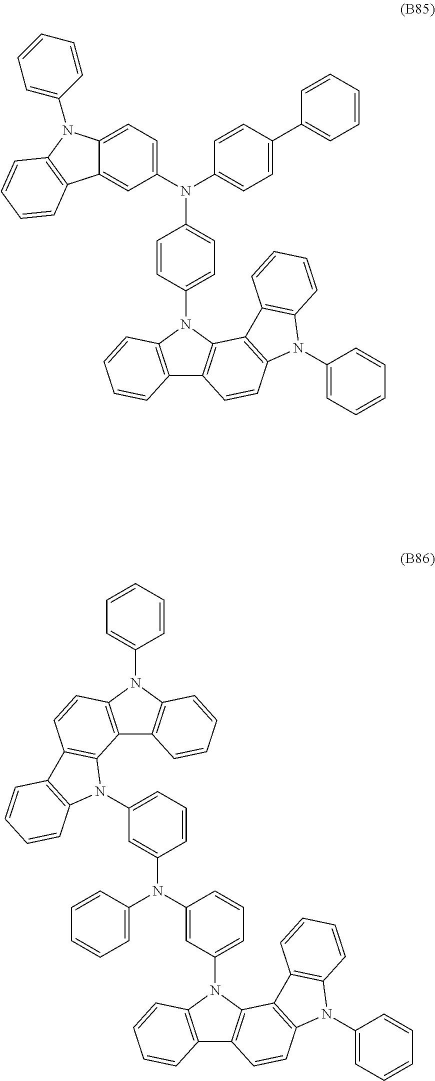

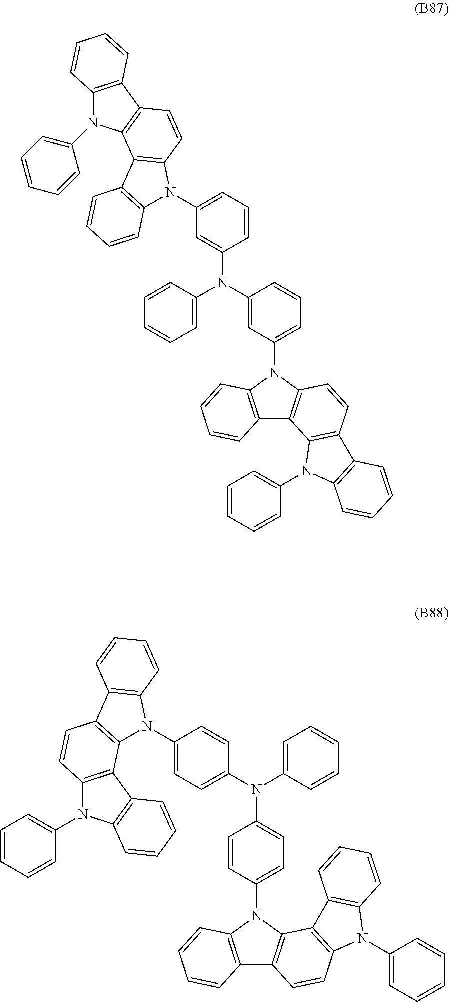

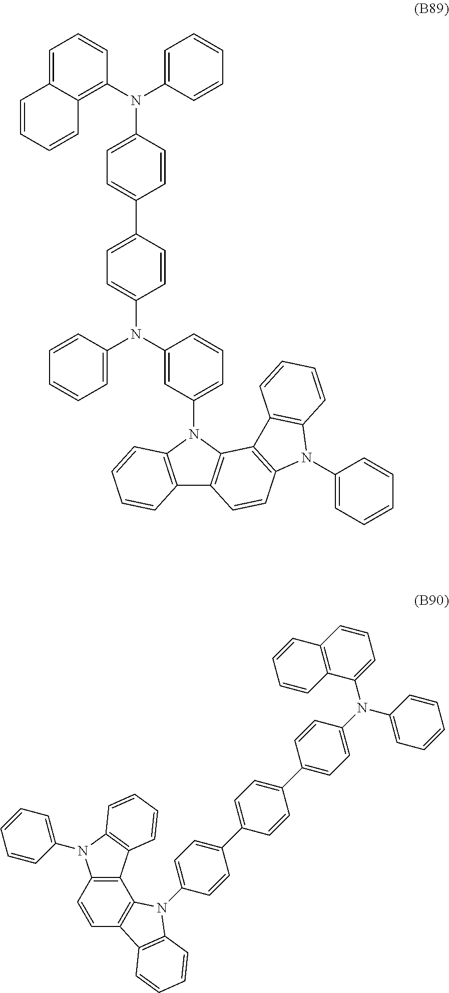

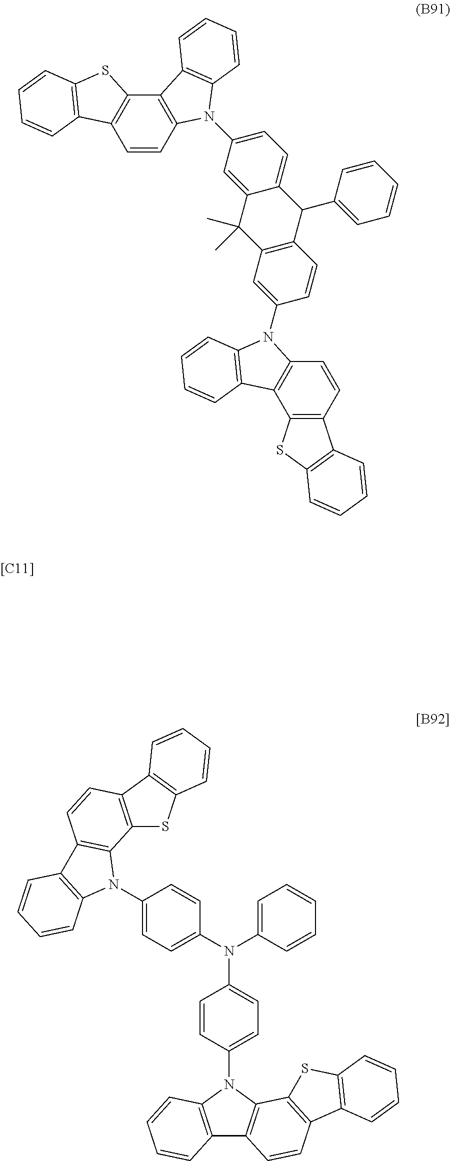

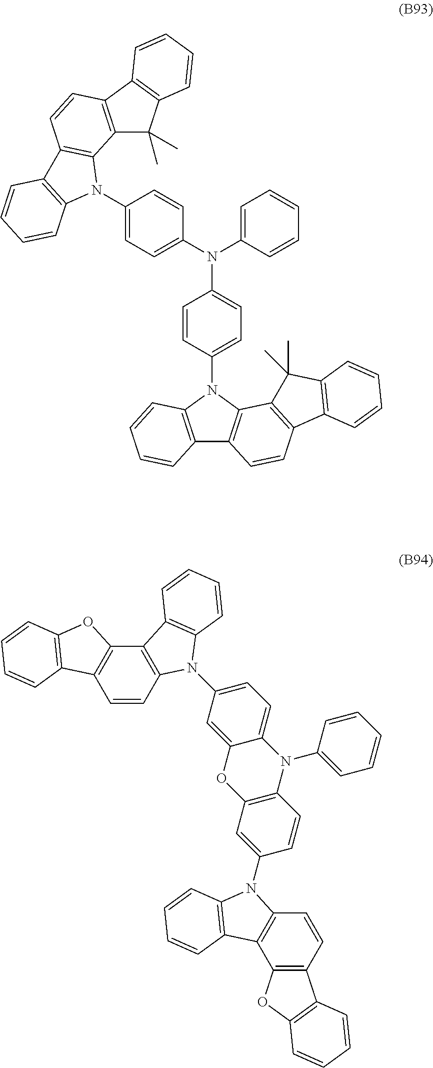

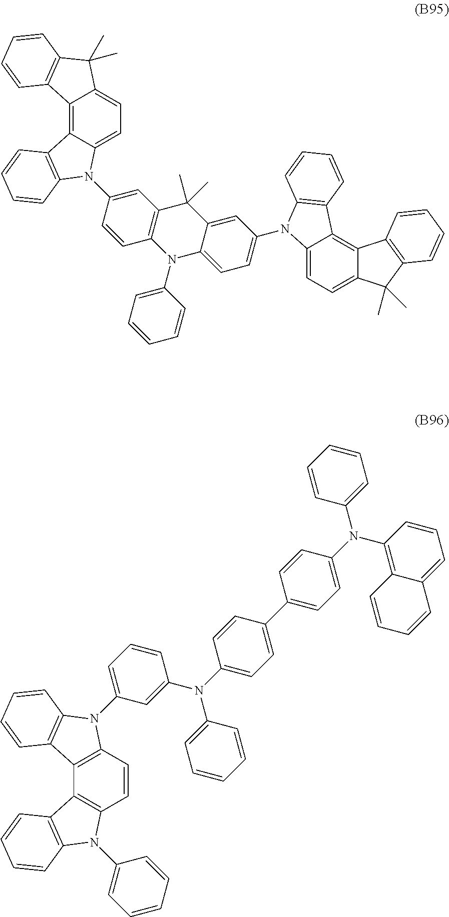

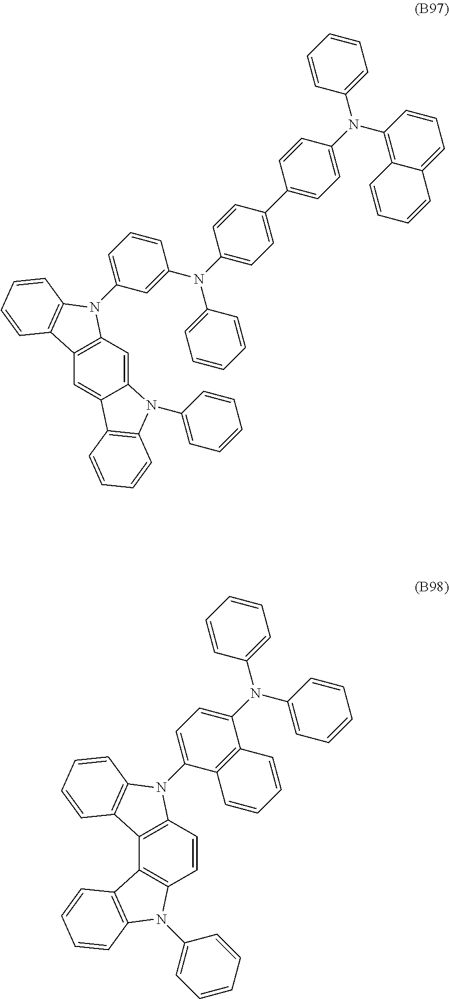

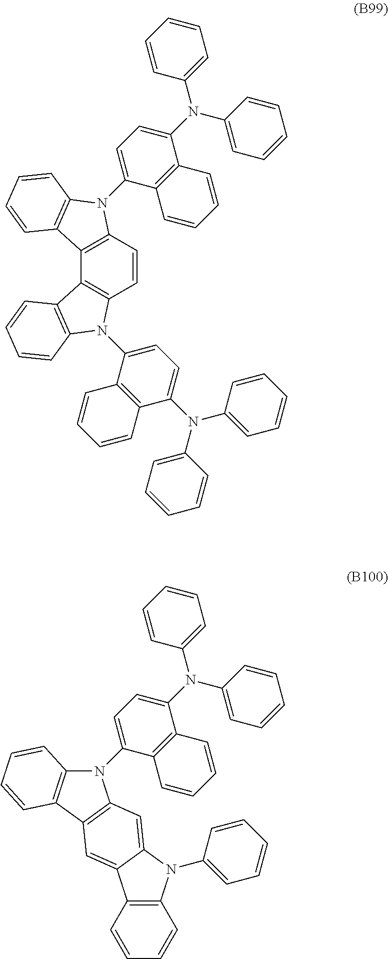

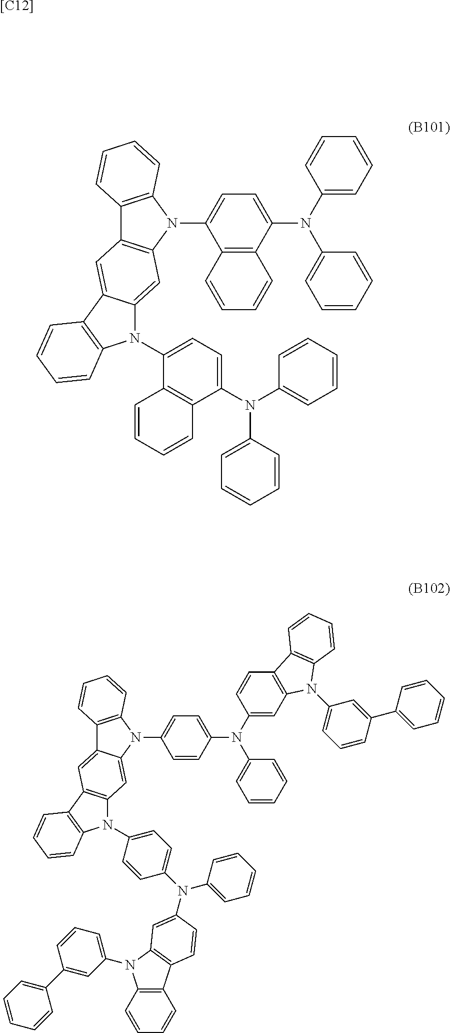

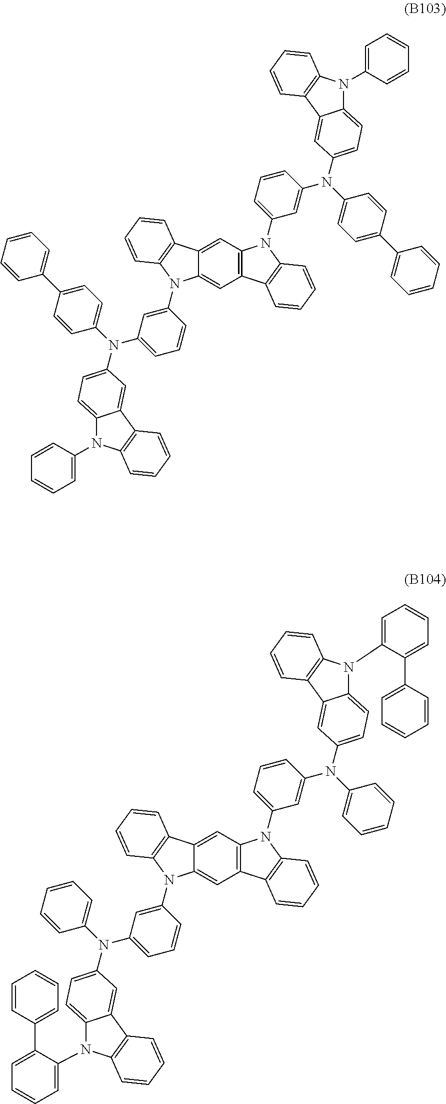

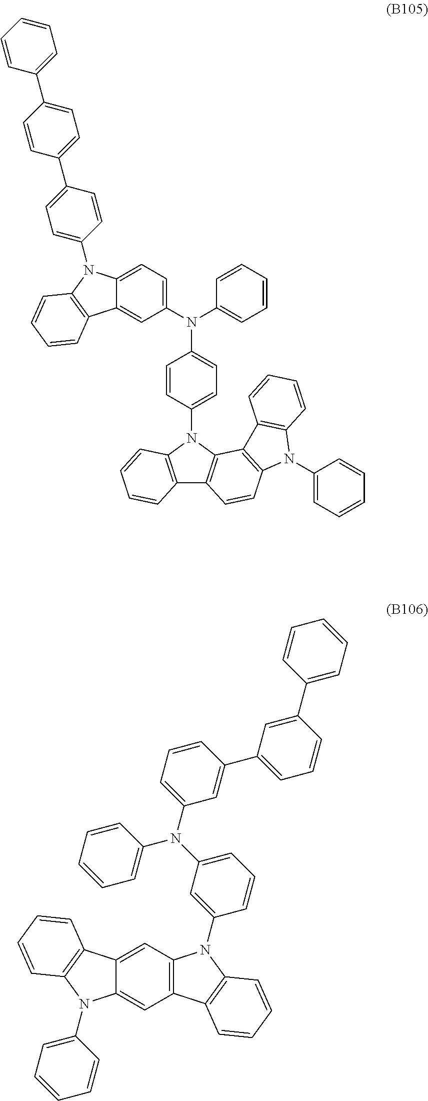

The material for a photoelectric conversion device of the present invention can be obtained by: synthesis by methods of various organic synthetic reactions established in the field of the organic synthetic chemistry including coupling reactions such as Suzuki coupling, Stille coupling, Grignard coupling, Ullmann coupling, Buchwald-Hartwig reaction, and Heck reaction, using commercially available reagents as raw materials; and then purification by using a known method such as recrystallization, column chromatography, and sublimation and purification. The method is not limited to this method.

The material for a photoelectric conversion device of the present invention preferably has an energy level of highest occupied molecular orbital (HOMO) obtained by structural optimization calculation with a density functional calculation B3LYP/6-31G(D) of −4.5 eV or lower, more preferably within a range of −4.8 eV to −6.0 eV.

An energy level of lowest unoccupied molecular orbital (LUMO) obtained by the above structural optimization calculation is preferably −2.5 eV or higher, more preferably within a range of −2.5 eV to −0.5 eV, and further preferably within a range of −1.8 eV to −0.8 eV.

In the material for a photoelectric conversion device of the present invention, a difference (absolute value) between the HOMO energy level and the LUMO energy level is preferably within a range of 2.0 to 5.0 eV, and more preferably within a range of 2.5 to 4.0 eV.

The material for a photoelectric conversion device of the present invention preferably has a hole mobility of 1×10⁻⁶ cm²/Vs to 1 cm²/Vs, more preferably has a hole mobility of 1×10⁻⁵ cm²/Vs to 1×10−1 cm²/Vs. The hole mobility can be evaluated by known methods such as a method with a FET-type transistor device, a method with a time-of-flight method, and an SCLC method.

The material for a photoelectric conversion device of the present invention is preferably amorphous. The amorphousness can be confirmed by various methods, and can be confirmed by, for example, detecting no peak in an XRD method or by detecting no endothermic peak in a DSC method.

Next, a photoelectric conversion device for imaging using the material for a photoelectric conversion device of the present invention will be described, but a structure of the photoelectric conversion device for imaging of the present invention is not limited thereto. The description will be made with reference to the drawings.

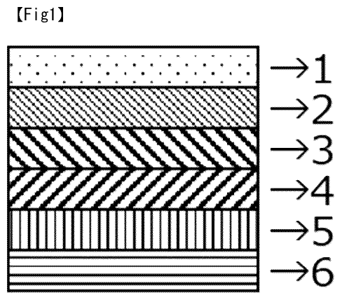

FIG. 1 is a sectional view schematically illustrating a structure of the photoelectric conversion device for imaging using the material for a photoelectric conversion device for imaging of the present invention. In FIG. 1, 1 represents an electrode, 2 represents a hole blocking layer, 3 represents a photoelectric conversion layer, 4 represents an electron blocking layer, 5 represents an electrode, and 6 represents a substrate. The photoelectric conversion device is not limited to the structure in FIG. 1, and adding or omitting a layer can be made as necessary. A structure inverted from that in FIG. 1, that is, the electrode 5, the hole blocking layer 4, the photoelectric conversion layer 3, the electron blocking layer 2, and the electrode 1 may be laminated in this order on the substrate 6, and also in this case, adding or omitting a layer can be made as necessary. Note that, in the photoelectric conversion device for imaging as described above, a layer to constitute the laminate structure on the substrate other than the electrode such as a positive electrode and a negative electrode may be collectively referred to as “organic layer”.

Hereinafter, each member and each layer of the photoelectric conversion device of the present invention will be described.

### —Substrate—

The photoelectric conversion device is preferably supported on a substrate. This substrate is not particularly limited, and a substrate composed of glass, a transparent plastic, quartz, or the like may be used, for example.

### —Electrode—

An electrode used for the photoelectric conversion device for imaging of the present invention has a function of trapping a hole and an electron generated in the photoelectric conversion layer. A function to let light enter the photoelectric conversion layer is also required. Thus, at least one of two electrodes is desirably transparent or semi-transparent. A material used for the electrode is not particularly limited as long as it has conductivity, and examples thereof include: conductive transparent materials, such as ITO, IZO, SnO₂, ATO (antimony-doped tin oxide), ZnO, AZO (Al-doped zinc oxide), GZO (gallium-doped zinc oxide), TiO₂, and FTO; metals, such as gold, silver, platinum, chromium, aluminum, iron, cobalt, nickel, and tungsten; inorganic conductive substances, such as copper iodide and copper sulfide; and conductive polymers, such as polythiophene, polypyrrole, and polyaniline. A plurality of these materials may be mixed to use as necessary. In addition, two or more layers thereof may be stacked.

### —Photoelectric Conversion Layer—

The photoelectric conversion layer is a layer in which a hole and an electrode are generated by charge separation of an exciton generated by the incident light. The photoelectric conversion layer may be formed with a single photoelectric converting material, or may be formed by combination with a P-type organic semiconductor material being a hole transport material and an N-type organic semiconductor material being an electron transport material. Two or more kinds of the P-type organic semiconductor may be used, and two or more kinds of the N-type organic semiconductor may be used. One or more kinds of these P-type organic semiconductor and/or N-type organic semiconductor desirably use a dye material having a function of absorbing light with a desired wavelength in the visible region. As the P-type organic semiconductor material being the hole transport material, the material for a photoelectric conversion device of the present invention can be used.

The P-type organic semiconductor material may be any material having a hole transportability. The material for a photoelectric conversion device of the present invention is preferably used, but another P-type organic semiconductor material may be used. Two or more types of the compound represented by the general formula (1) or the general formula (2) (the material for a photoelectric conversion device of the present invention) may be mixed to use. Furthermore, the above compound and another P-type organic semiconductor material may be mixed to use.

The another P-type organic semiconductor material may be any material having the hole transportability, and examples thereof include: aromatic compounds such as a naphthalene derivative, an anthracene derivative, a phenanthrene derivative, a pyrene derivative, a chrysene derivative, a naphthacene derivative, a triphenylene derivative, a perylene derivative, a fluoranthene derivative, a fluorene derivative, a cyclopentadiene derivative, a furan derivative, a thiophene derivative, a pyrrole derivative, a benzofuran derivative, a dibenzothiophene derivative, a dinaphthothienothiophene derivative, an indole derivative, a pyrazoline derivative, a dibenzofuran derivative, a dibenzothiophene derivative, a carbazole derivative, and indolocarbazole; an aromatic amine derivative, a styrylamine derivative, a benzidine derivative, a porphyrin derivative, a phthalocyanine derivative, and a quinacridone derivative.

As the P-type organic semiconductor material, a polymer material may be used. Examples of the polymer P-type organic semiconductor material include a polyphenylene-vinylene derivative, a polyparaphenylene derivative, a polyfluorene derivative, a polyvinylcarbazole derivative, and a polythiophene derivative. Two or more kinds selected from the compounds represented by the general formula (1) or the general formula (2) of the present invention, the P-type organic semiconductor material, and the polymer P-type organic semiconductor material may be mixed to use.

The N-type organic semiconductor material may be any material having the electron transportability, and examples thereof include naphthalenetetracarboxylic diimide and perylenetetracarboxylic diimide, fullerenes (fullerene derivative), and azole derivatives such as imidazole, thiazole, thiadiazole, oxazole, oxadiazole, and triazole. Two or more kinds of materials selected from the N-type organic semiconductor materials may be mixed to use.

### —Electron Blocking Layer—

The electron blocking layer is provided in order to inhibit a dark current generated by injecting an electron from one electrode into the photoelectric conversion layer when a bias voltage is applied between the two electrodes. The electron blocking layer also has a function of hole transportation for transporting a hole generated by charge separation in the photoelectric conversion layer toward the electrode. A single layer or multiple layers of the electron blocking layer can be disposed as necessary. For the electron blocking layer, a P-type organic semiconductor material being the hole transport material can be used. The P-type organic semiconductor material may be any material having the hole transportability. Although the compound represented by the general formula (1) or the general formula (2) is preferably used, another P-type organic semiconductor material may be used. In addition, the compound represented by the general formula (1) or the general formula (2) and the other P-type organic semiconductor material as noted above or a polymer P-type organic semiconductor material may be mixed to use.

### —Hole Blocking Layer—

The hole blocking layer is provided in order to inhibit a dark current generated by injecting a hole from one electrode into the photoelectric conversion layer when a bias voltage is applied between the two electrodes. The hole blocking layer also has a function of electron transportation for transporting an electron generated by charge separation in the photoelectric conversion layer toward the electrode. A single layer or multiple layers of the hole blocking layer can be disposed as necessary. For the hole blocking layer, the N-type organic semiconductor material having the electron transportability can be used. The N-type organic semiconductor material may be any material having the electron transportability, and examples thereof include: polycyclic aromatic multivalent carboxylic anhydride or imidized products thereof, such as naphthalenetetracarboxylic diimide and perylenetetracarboxylic diimide; fullerenes (fullerene derivative), such as C60 and C70; azole derivatives, such as imidazole, thiazole, thiadiazole, oxazole, oxadiazole, and triazole; a tris(8-quinolinolate)aluminum (III) derivative, a phosphine oxide derivative, a nitro-substituted fluorene derivative, a diphenylquinone derivative, a thiopyran dioxide derivative, a carbodiimide, a fluorenylidenemethane derivative, an anthraquinodimethane derivative and an anthrone derivative, a bipyridine derivative, a quinoline derivative, and an indolocarbazole derivative. Two or more kinds of materials selected from the N-type organic semiconductor materials may be mixed to use.

Hydrogen in the material of the present invention may be deuterium. That is, a part or all of hydrogens on the aromatic ring, in addition to hydrogens on the aromatic ring in the general formula (1), (2), (3a) to (3d) and including the substituent Ar¹, Ar², Ra, Ar¹, Ar⁴, Rb, Ar⁵, Ar⁶ may be a deuterium.

Furthermore, a part or all of hydrogens in a compound used as the N-type organic semiconductor material and the P-type organic semiconductor material may be deuterium.

A method for producing a film of each layer in producing the photoelectric conversion device for imaging of the present invention is not particularly limited. The photoelectric conversion device may be produced by any one of dry process and wet process.

The organic layer containing the material for a photoelectric conversion device of the present invention may be a plurality of layers as necessary.

### EXAMPLES

Hereinafter, the present invention will be described in more detail with Examples, but the present invention is not limited to these Examples.

### Calculation Example

### Calculation of HOMO and LUMO Values

Calculated were HOMO and LUMO for the above compounds B1, B2, B3, B9, B61, B65, and B94. The calculation was performed by using a density functional theory (DFT), using Gaussian as a calculation program, and with structural optimization calculation of a density functional calculation B3LYP/6-31G(d). Table 1 shows the results. It can be mentioned that any of the materials of the present invention has preferable HOMO and LUMO values.

As comparison, HOMO and LUMO for the compounds H1, H2, H3 and H4 were calculated by the same method as the above method. Table 1 shows the results.

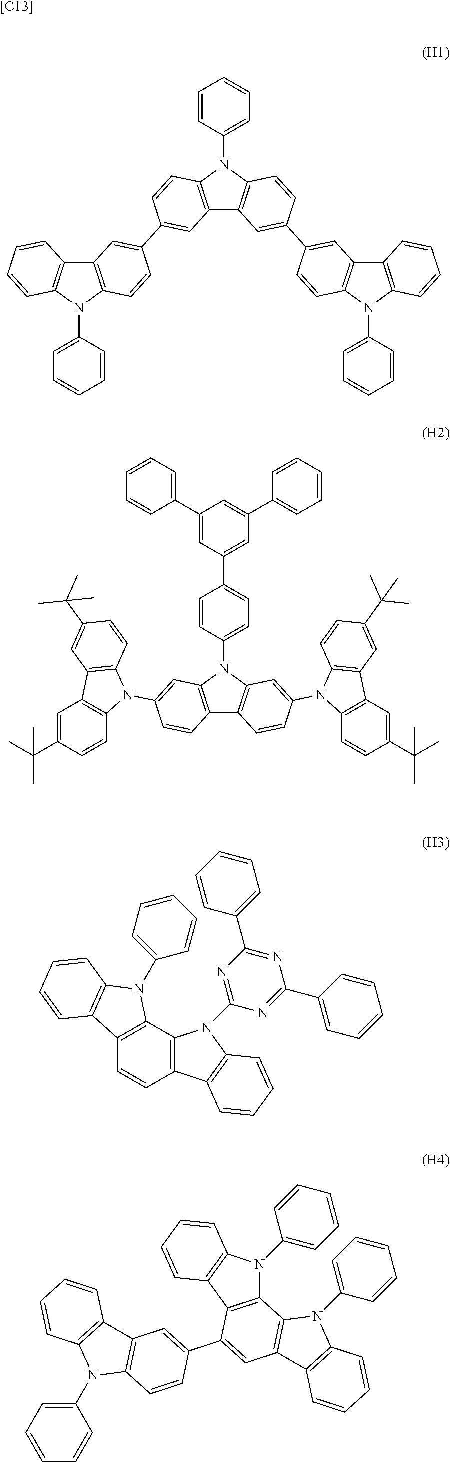

TABLE 1

| Compound | HOMO[eV] | LUMO[eV] |
|---|---|---|
| B1 | −4.7 | −1.0 |
| B2 | −4.7 | −1.2 |
| B3 | −4.9 | −1.2 |
| B9 | −4.7 | −1.3 |
| B61 | −4.8 | −0.8 |
| B65 | −4.9 | −0.9 |
| B94 | −4.9 | −1.0 |
| H1 | −4.9 | −0.7 |
| H2 | −5.0 | −1.3 |
| H3 | −5.3 | −1.9 |
| H4 | −4.9 | −0.8 |

Synthesis examples of the compounds B1, B2, B3, and B61 will be described below as representative examples. The other compounds were also synthesized in the similar method.

### Synthesis Example 1 (Synthesis of Compound B1)

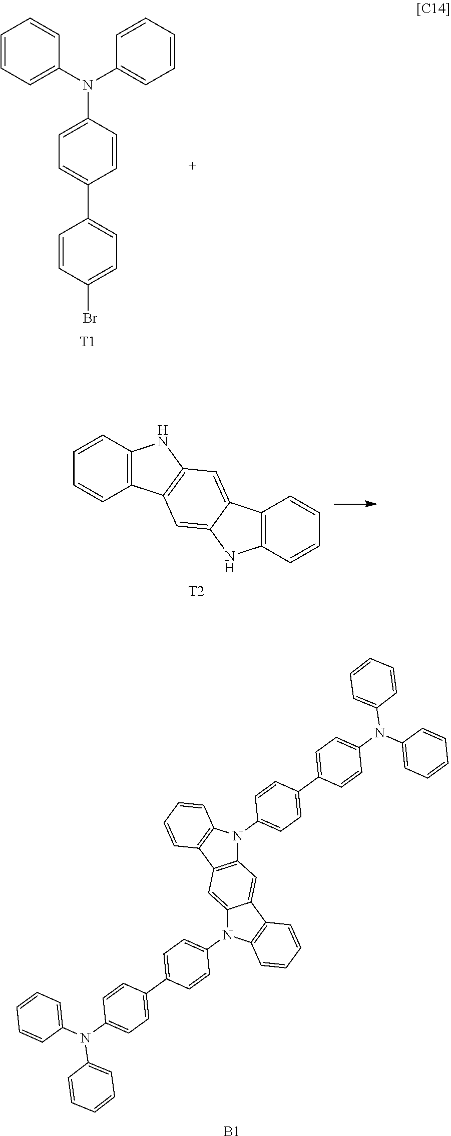

Into a three-necked 200-ml flask with degassed and nitrogen-replenished, T1 (17.2 mmol), T2 (7.8 mmol), copper iodide (2.3 mmol), potassium carbonate (23.4 mmol), and 8-quinolinol (2.3 mmol) were added, 40 ml of 1,3-dimethyl-2-imidazolidinone (DMI) was added thereinto, and then the mixture was stirred at 190° C. for 16 hours. The mixture was once cooled to a room temperature, then 100 ml of water was added, and the generated white precipitate was collected by filtration. The obtained residue was reprecipitated with xylene to obtain the compound B1 (white solid). The yield was 31%. The obtained solid was evaluated by the XRD method, but no peak was detected. (APCI-TOFMS, m/z 895 [M+H]⁺)

### Synthesis Example 2 (Synthesis of Compound B2)

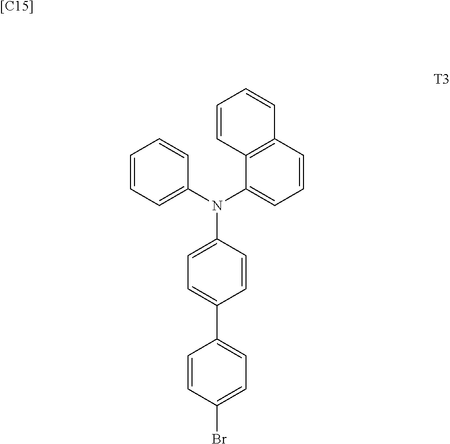

The compound B2 (white solid) was obtained in the same manner as in Synthesis Example 1 except that T1 was changed to T3. The yield was 45%. The obtained solid was evaluated by the XRD method, but no peak was detected. (APCI-TOFMS, m/z 995 [M+H]⁺)

### Synthesis Example 3 (Synthesis of Compound B3)

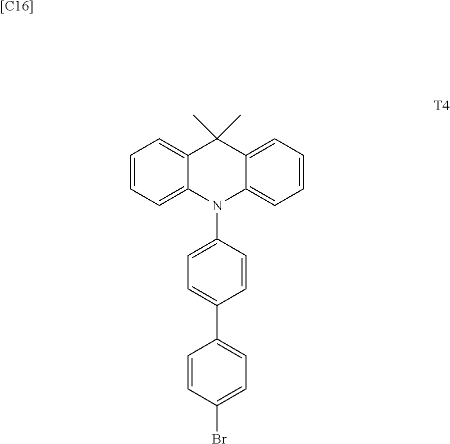

The compound B3 (white solid) was obtained in the same manner as in Synthesis Example 1 except that T1 was changed to T4. The yield was 53%. The obtained solid was evaluated by the XRD method, but no peak was detected. (APCI-TOFMS, m/z 975[M+H]⁺)

### Synthesis Example 4 (Synthesis of Compound B61)

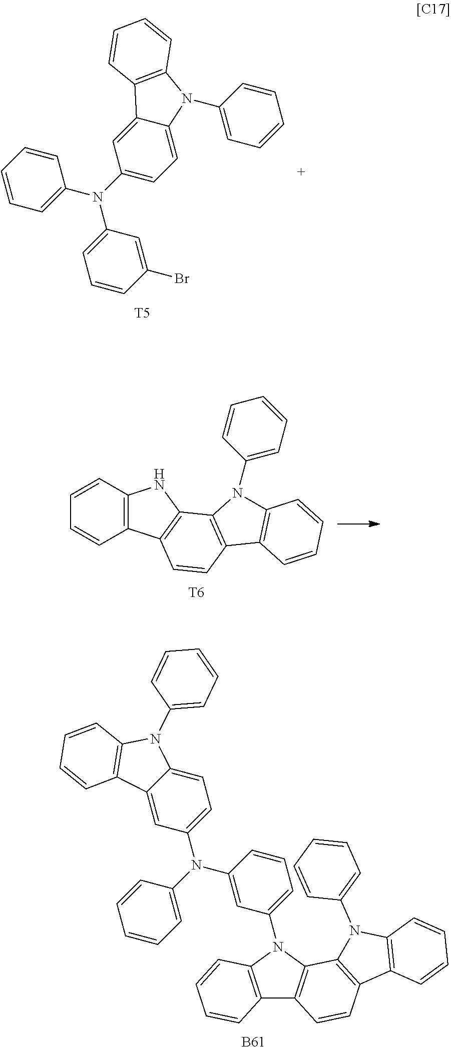

Into a three-necked 200-ml flask with degassed and nitrogen-replenished, T5 (12.0 mmol), T6 (6.0 mmol), copper iodide (1.8 mmol), potassium carbonate (18.1 mmol), and 8-quinolinol (1.8 mmol) were added, 30 ml of 1,3-dimethyl-2-imidazolidinone (DMI) was added thereinto, and then the mixture was stirred at 190° C. for 48 hours. The mixture was once cooled to a room temperature, then 100 ml of water was added, and the generated white precipitate was collected by filtration. The obtained residue was purified by column chromatography to obtain the compound B61 (white solid). The yield was 66%. The obtained solid was evaluated by the XRD method, but no peak was detected. (APCI-TOFMS, m/z 741 [M+H]⁺)

### Measurement of Charge Mobility

On an electrode composed of ITO with 110 nm in film thickness formed on a glass substrate, the compound B1 was produced to a film as an organic layer by a vacuum deposition method under a condition that a film thickness was approximately 3 μm. Subsequently, charge mobility was measured by a time-of-flight method using a device in which aluminum (Al) was formed with 70 nm in thickness as an electrode. The hole mobility was 6.4×10⁻⁴ cm²/Vs.

The hole mobility was measured by the same method as above except that compounds shown in Table 2 were used instead of the compound B1.

Table 2 shows the results.

TABLE 2

| Compound | Hole mobility [cm²/Vs] |
|---|---|
| B1 | 6.4 × 10⁻⁴ |
| B2 | 6.0 × 10⁻⁴ |
| B3 | 3.6 × 10⁻⁴ |
| B9 | 8.0 × 10⁻⁴ |
| B61 | 2.4 × 10⁻⁴ |
| B65 | 1.3 × 10⁻⁴ |
| B94 | 7.1 × 10⁻⁵ |
| H3 | 4.0 × 10⁻⁵ |
| H4 | 9.3 × 10⁻⁶ |

### Example 1

On an electrode composed of ITO with 70 nm in film thickness formed on a glass substrate, a 100-nm film of the compound B1 was formed with a vacuum degree of 4.0×10⁻⁵ Pa as an electron blocking layer. Then, a 100-nm thin film of quinacridone was formed as a photoelectric conversion layer. Finally, a 70-nm aluminum film was formed as an electrode to produce a photoelectric conversion device.

A voltage of 2 V was applied between the ITO electrode and the aluminum electrode. In this time, a current in a dark place was 1.5×10⁻¹⁰ A/cm². When a voltage of 2 V was applied and the ITO electrode side was irradiated with light with an irradiation light wavelength of 500 nm and 1.6 μW/cm², a current was 1.4×10⁻⁷ A/cm². A contrast ratio was calculated to be 9.3×10².

### Comparative Example 1

On an electrode, which was formed on a glass substrate, composed of ITO with 70 nm in film thickness, a 100-nm film of the compound H1 was formed with a vacuum degree of 4.0×10⁻⁵ Pa as an electron blocking layer. Then, a 100-nm film of quinacridone was formed as a photoelectric conversion layer. Finally, a 70-nm aluminum film was formed as an electrode to produce a photoelectric conversion device.

On this photoelectric conversion device, a current when a voltage of 2 V was applied in a dark place and a current with light irradiation were measured in the same manner as in Example 1. The current in a dark place was 5.6×10⁻⁹ A/cm², and the current with light irradiation was 1.2×10⁻⁷ A/cm². A contrast ratio was calculated to be 0.21×10² A/cm².

Table 3 shows the evaluation results of Example 1 and Comparative Example 1.

TABLE 3

| | | | Current value | |
|---|---|---|---|---|
| | | Current value | in light | |
| | | in dark place | irradiation | Contrast |
| | Compound | [A/cm²] | [A/cm²] | ratio |
| Example 1 | B1 | 1.5 × 10⁻¹⁰ | 1.4 × 10⁻⁷ | 9.3 × 10² |
| Comparative | H1 | 5.6 × 10⁻⁹ | 1.2 × 10⁻⁷ | 2.1 × 10¹ |
| Example 1 | | | | |

### Example 2

On an electrode composed of ITO with 70 nm in film thickness and formed on a glass substrate, a 10-nm film of the compound B1 was formed with a vacuum degree of 2.5×10⁻⁵ Pa as an electron blocking layer. Then, 2Ph-BTBT, F6-SubPc-OC6F5, and fullerene (C60) were co-deposited at a deposition rate ratio of 4:4:2 with 200 nm to form a film as a photoelectric conversion layer. Subsequently, 10-nm of dpy-NDI was deposited to form a hole blocking layer. Finally, an aluminum film was formed with 70 nm in thickness as an electrode to produce a photoelectric conversion device. A current in a dark place (dark current) was 6.6×10⁻¹⁰ A/cm² with the electrodes of ITO and aluminum and with applying a voltage of 2.6 V. When a voltage of 2.6 V was applied and the ITO electrode side was irradiated with light with an LED adjusted to be an irradiation light wavelength of 500 nm and 1.6 μW from a height of 10 cm, a current (bright current) was 3.4×10⁻² A/cm². A contrast ratio was 5.2×10² with applying a voltage of 2.6 V. Table 4 shows the result thereof.

### Examples 3 to 5

Photoelectric conversion devices were produced in the same manner as in Example 2 except that compounds shown in Table 4 were used as the electron blocking layer.

### Comparative Examples 2 to 3

Photoelectric conversion devices were produced in the same manner as in Example 2 except that compounds shown in Table 4 were used as the electron blocking layer.

Table 4 shows the results of Examples 3 to 5 and Comparative Examples 2 to 3.

The compounds used in Examples and Comparative Examples are shown below.

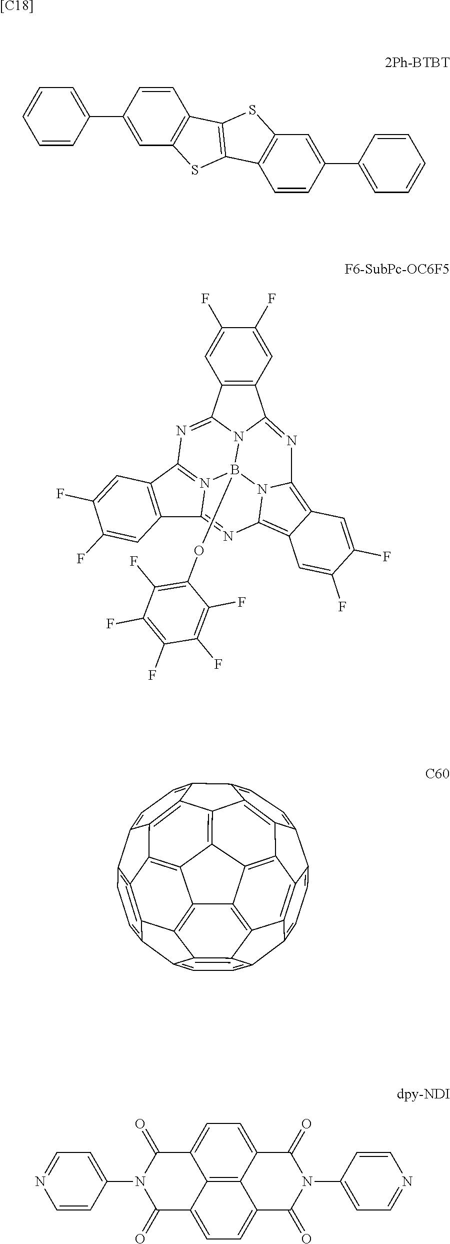

TABLE 4

| | | | Current value | |
|---|---|---|---|---|
| | | Current value | in light | |
| | | in dark place | irradiation | Contrast |
| | Compound | [A/cm²] | [A/cm²] | ratio |
| Example 2 | B1 | 6.6 × 10⁻¹⁰ | 3.4 × 10⁻⁷ | 5.2 × 10² |
| Example 3 | B9 | 1.1 × 10⁻¹⁰ | 2.7 × 10⁻⁷ | 2.5 × 10³ |
| Example 4 | B65 | 5.8 × 10⁻¹⁰ | 3.3 × 10⁻⁷ | 5.7 × 10² |
| Example 5 | B94 | 9.5 × 10⁻¹¹ | 2.9 × 10⁻⁷ | 3.1 × 10³ |
| Comparative | H1 | 6.9 × 10⁻⁹ | 3.1 × 10⁻⁷ | 4.5 × 10¹ |
| Example 2 | | | | |
| Comparative | H3 | 7.5 × 10⁻¹⁰ | 2.5 × 10⁻⁷ | 3.3 × 10² |
| Example 3 | | | | |

It is found from the results that the compounds of the present invention exhibit excellent contrast ratio compared with the comparative compounds, and are obviously useful as the material for a photoelectric conversion device for imaging.

### REFERENCE SIGNS LIST

1 Substrate
2 Hole blocking layer
3 Photoelectric conversion layer
4 Electron blocking layer
5 Electrode
6 Substrate

1. A material for a photoelectric conversion device for imaging, represented by the following general formula (1) or (2): 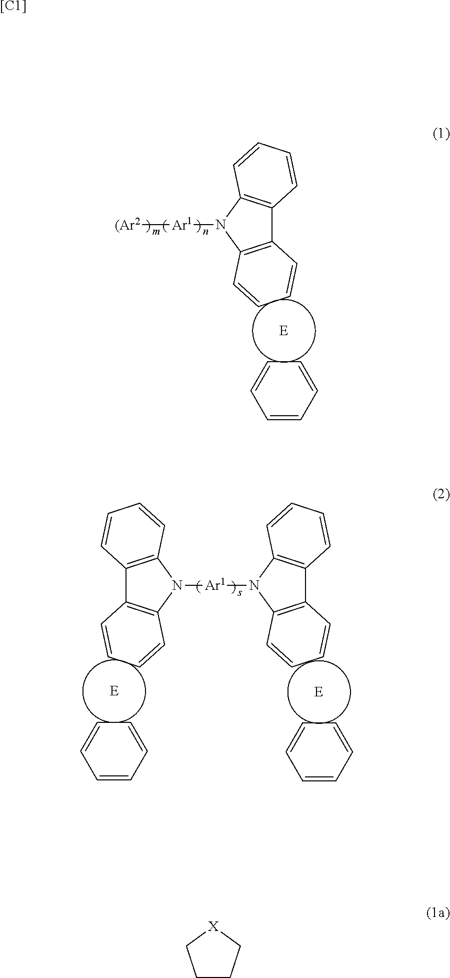
wherein a ring E independently represents a heterocyclic ring condensed with an adjacent ring at any position and represented by the formula (1a),
X represents O, S, C(Ra)₂, or N—(Ar⁵)ₚ—(Ar⁶)_{q},
Ar¹, Ar², Ar⁵, and Ar⁶ each independently represent a substituted or unsubstituted diarylamino group having 12 to 30 carbon atoms, a substituted or unsubstituted arylheteroarylamino group having 12 to 30 carbon atoms, a substituted or unsubstituted diheteroarylamino group having 12 to 30 carbon atoms, a substituted or unsubstituted aromatic hydrocarbon group having 6 to 30 carbon atoms, or a substituted or unsubstituted heteroaromatic group having 4 to 18 carbon atoms,
“n”, “p”, and “s” represent the number of repetition, “n” and “p” independently represent an integer of 0 to 4, and “s” represents an integer of 1 to 4; “m” and “q” independently represent the number of substitution, and represent an integer of 1 to 3; provided that when “n” represents 0, “m” represents 1, and when “p” represents 0, “q” represents 1,
Ra each independently represents an alkyl group having 1 to 20 carbon atoms, a substituted or unsubstituted aromatic hydrocarbon group having 6 to 30 carbon atoms, or a substituted or unsubstituted heteroaromatic group having 4 to 18 carbon atoms,
at least one Ar¹, Ar², Ar⁵, or Ar⁶ is represented by a substituted or unsubstituted diarylamino group having 12 to 30 carbon atoms, a substituted or unsubstituted arylheteroarylamino group having 12 to 30 carbon atoms, a substituted or unsubstituted diheteroarylamino group having 12 to 30 carbon atoms, or any one of the following formulae (3a) to (3d) in which the amino group is further condensed; provided that a case of being represented by a group in which the amino group in Ar¹ or Ar⁵ is further condensed is represented by the following formula (3a) or (3b), and a case of being represented by a group in which the amino group in Ar² or Ar⁶ is further condensed is represented by the following formula (3c) or (3d), 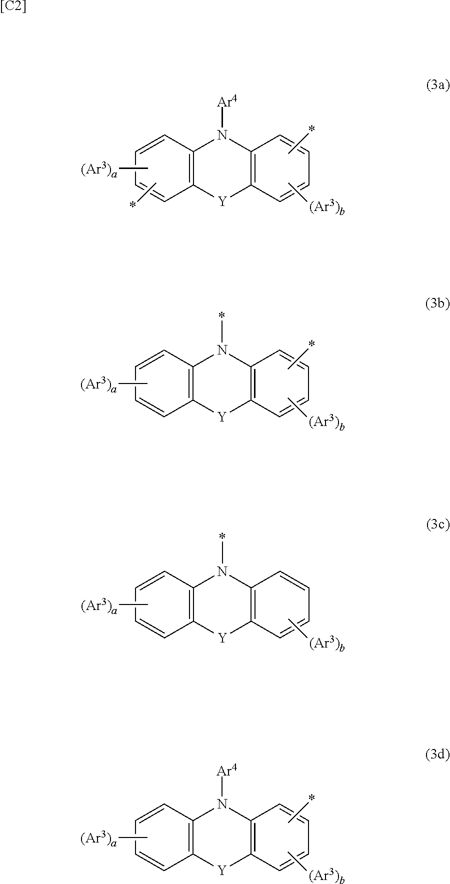
wherein Y is each independently represented by a single bond, Si(Rb)₂, C(Rb)₂, O, S, Se, or N—Rb; Rb each independently represents an alkyl group having 1 to 20 carbon atoms, a substituted or unsubstituted aromatic hydrocarbon group having 6 to 30 carbon atoms, or a substituted or unsubstituted heteroaromatic group having 4 to 18 carbon atoms; Ar³ and Ar⁴ each independently represent a substituted or unsubstituted diarylamino group having 12 to 30 carbon atoms, a substituted or unsubstituted arylheteroarylamino group having 12 to 30 carbon atoms, a substituted or unsubstituted diheteroarylamino group having 12 to 30 carbon atoms, a substituted or unsubstituted aromatic hydrocarbon group having 6 to 30 carbon atoms, or a substituted or unsubstituted heteroaromatic group having 4 to 18 carbon atoms; “a” and “b” represent the number of substitution and each independently represent 0 to 3; and “*” represents a bonding position.

2. The material for a photoelectric conversion device for imaging according to claim 1, wherein X is represented by O, S, or N—(Ar⁵)ₚ—(Ar⁶)_{q}.

3. The material for a photoelectric conversion device for imaging according to claim 2, wherein at least one of Ar¹, Ar², Ar⁵, and Ar⁶ is represented by a substituted or unsubstituted diarylamino group having 12 to 30 carbon atoms, a substituted or unsubstituted arylheteroarylamino group having 12 to 30 carbon atoms, or a substituted or unsubstituted diheteroarylamino group having 12 to 30 carbon atoms.

4. The material for a photoelectric conversion device for imaging according to claim 3, wherein at least one of Ar¹, Ar², Ar⁵, and Ar⁶ is represented by a substituted or unsubstituted diarylamino group having 12 to 30 carbon atoms or a substituted or unsubstituted arylheteroarylamino group having 12 to 27 carbon atoms.

5. The material for a photoelectric conversion device for imaging according to claim 4, wherein at least two of Ar¹, Ar², Ar⁵, and Ar⁶ are represented by a substituted or unsubstituted diarylamino group having 12 to 30 carbon atoms or a substituted or unsubstituted arylheteroarylamino group having 12 to 27 carbon atoms.

6. The material for a photoelectric conversion device for imaging according to claim 1, wherein at least one of Ar¹, Ar², Ar⁵, and Ar⁶ is represented by any one of the formulae (3a) to (3d), provided that Ar¹ and Ar⁵ are selected from the formula (3a) or (3b), and Ar² and Ar⁶ are selected from the formula (3c) or (3d).

7. The material for a photoelectric conversion device for imaging according to claim 1, wherein Y is represented by any one of Si(Rb)₂, C(Rb)₂, O, or S.

8. The material for a photoelectric conversion device for imaging according to claim 1, wherein at least two of Ar¹, Ar², Ar⁵, and Ar⁶ are represented by any one of the formulae (3a) to (3d), provided that Ar¹ is independently selected from the formula (3a) or (3b), and Ar² is selected from the formula (3c) or (3d).

9. The material for a photoelectric conversion device for imaging according to claim 1, wherein, in the general formula (1), at least any one of the following requirement (i), (ii), (iii), (iv), (v), (vi), (vii), or (viii) is satisfied:
(i) in a case of n=2 to 4, at least one pair of Ar¹ adjacent to each other represent phenyl groups to form a biphenyl group;
(ii) Ar¹ and Ar² adjacent to each other represent phenyl groups to form a biphenyl group;
(iii) in a case of p=2 to 4, at least one pair of Ar⁵ adjacent to each other represent phenyl groups to form a biphenyl group;
(iv) Ar⁵ and Ar⁶ adjacent to each other represent phenyl groups to form a biphenyl group;
(v) at least one Ar¹ represents a substituted or unsubstituted diarylamino group having 12 to 30 carbon atoms or a substituted or unsubstituted arylheteroarylamino group having 12 to 27 carbon atoms, and has at least one biphenyl group as an aryl group of the amino group;
(vi) at least one Ar² represents a substituted or unsubstituted diarylamino group having 12 to 30 carbon atoms or a substituted or unsubstituted arylheteroarylamino group having 12 to 27 carbon atoms, and has at least one biphenyl group as an aryl group of the amino group;
(vii) at least one Ar⁵ represents a substituted or unsubstituted diarylamino group having 12 to 30 carbon atoms or a substituted or unsubstituted arylheteroarylamino group having 12 to 27 carbon atoms, and has at least one biphenyl group as an aryl group of the amino group; and
(viii) at least one Ar⁶ represents a substituted or unsubstituted diarylamino group having 12 to 30 carbon atoms or a substituted or unsubstituted arylheteroarylamino group having 12 to 27 carbon atoms, and an aryl group of the amino group has at least one biphenyl group.

10. The material for a photoelectric conversion device for imaging according to claim 9, wherein, in the general formula (1), at least two of the requirements (i) to (viii) are satisfied.

11. The material for a photoelectric conversion device for imaging according to claim 1, wherein further at least one of Ar¹, Ar², Ar⁵, or Ar⁶ represents a carbazolyl group, a dibenzofuran group, or a dibenzothiophene group.

12. The material for a photoelectric conversion device for imaging according to claim 1, wherein an energy level of highest occupied molecular orbital (HOMO) obtained by structural optimization calculation with a density functional calculation B3LYP/6-31G(d) is −4.5 eV or lower.

13. The material for a photoelectric conversion device for imaging according to claim 1, wherein an energy level of lowest unoccupied molecular orbital (LUMO) obtained by structural optimization calculation with a density functional calculation B3LYP/6-31G(d) is −2.5 eV or higher.

14. The material for a photoelectric conversion device for imaging according to claim 1, wherein the material has a hole mobility of 1×10⁻⁶ cm²/Vs or more.

15. The material for a photoelectric conversion device for imaging according to claim 1, wherein the material is amorphous.

16. The material for a photoelectric conversion device for imaging according to claim 1, wherein the material is used as a hole transport material of a photoelectric conversion device for imaging.

17. A photoelectric conversion device for imaging, comprising a photoelectric conversion layer and an electron blocking layer between two electrodes, wherein at least one layer of the photoelectric conversion layer and the electron blocking layer contains the material for a photoelectric conversion device for imaging according to claim 1.
